(19) United States
(12) Patent Application Publication
(10) Pub. No.: US 2026/0223583 A1
(43) Pub. Date: Jul. 30, 2026

(54) DISPLAY PANEL INCLUDING METAL LAYER HAVING PROTRUDING TIP AND ELECTRONIC DEVICE INCLUDING THE SAME

(71) Applicant: SAMSUNG DISPLAY CO., LTD., YONGIN-SI (KR)

(72) Inventors: Younjoo Ryu, YONGIN-SI (KR); Sanghyun Yun, YONGIN-SI (KR)

(21) Appl. No.: 19/440,035

(22) Filed: Jan. 5, 2026

(30) Foreign Application Priority Data
Jan. 24, 2025 (KR) 10-2025-0011890

(51) Int. Cl. H10K 59/80

(52) U.S. Cl. CPC H10K 59/8792; H10K 59/873

(57) ABSTRACT

A display panel includes a substrate, a display layer disposed on the substrate, an encapsulation layer disposed on the display layer, a metal layer disposed on the encapsulation layer and including a tip portion that protrudes in one direction, and a light absorption layer disposed on the metal layer.

### CROSS-REFERENCE TO RELATED APPLICATION

This application claims priority under 35 U.S.C. §119 to Korean Patent Application No. 10-2025-0011890, filed on January 24, 2025, in the Korean Intellectual Property Office, the disclosure of which is incorporated by reference herein in its entirety.

### TECHNICAL FIELD

One or more embodiments relate to a display panel, and more particularly, to a display panel including a metal layer having a protruding tip and an electronic device including the same.

### DISCUSSION OF THE RELATED ART

Electronic devices are available in both large and small form factors with many smaller electronic devices being designed for mobile use. In addition to small electronic devices such as mobile phones, tablet computers have recently been widely used as mobile electronic devices. Such mobile electronic devices include a display panel to provide visual information such as images or videos to a user in order to support various functions. Recently, as various parts for driving a display panel have been miniaturized, the proportion of a display panel in an electronic devices has increased gradually and today, many such electronic devices seem to be primarily made up of the display. Additionally, many electronic devices making use of display panels are capable of being bent from a flat state by a certain angle.

### SUMMARY

A display panel includes a substrate. A display layer is disposed on the substrate. An encapsulation layer is disposed on the display layer. A metal layer is disposed on the encapsulation layer and includes a first tip portion that protrudes in one direction. A light absorption layer is disposed on the metal layer.

The metal layer may include a first metal layer disposed on the encapsulation layer, and a second metal layer disposed on the first metal layer and including the first tip portion that protrudes further than a side surface of the first metal layer in a direction away from the side surface of the first metal layer.

The side surface of the first metal layer may be inclined.

The metal layer may further include a third metal layer disposed between the encapsulation layer and the first metal layer.

The second metal layer and the third metal layer may include a same material.

The third metal layer may include a second tip portion that protrudes further than a side surface of the first metal layer in a direction away from the side surface of the first metal layer.

The metal layer may further include a fourth metal layer disposed on the third metal layer, and a fifth metal layer disposed between the first metal layer and the fourth metal layer.

The fifth metal layer may include a different material from the second metal layer.

The fifth metal layer may include a third tip portion that protrudes further than a side surface of the first metal layer in a direction away from the side surface of the first metal layer.

A side surface of the fourth metal layer may be inclined.

The display panel may further include a light transmission layer surrounding the metal layer and the light absorption layer.

The display panel may further include a light control planarization layer disposed between the metal layer and the encapsulation layer.

The metal layer and the light absorption layer may be in a line shape, in a plan view.

The metal layer and the light absorption layer may be respectively provided as a plurality of metal layers and a plurality of light absorption layers, and the plurality of metal layers and the plurality of light absorption layers may be alternately stacked.

The metal layer and the light absorption layer may be spaced apart from each other in a height direction of the light absorption layer.

A side surface of the light absorption layer may be inclined.

An electronic device includes a display module, and a memory storing data for an operation of the display module. The display module includes a substrate, a display layer disposed on the substrate, an encapsulation layer disposed on the display layer, a metal layer disposed on the encapsulation layer and including a first tip portion that protrudes in one direction, and a light absorption layer disposed on the metal layer.

The metal layer may include a first metal layer disposed on the encapsulation layer, and a second metal layer disposed on the first metal layer and including the first tip portion that protrudes further than a side surface of the first metal layer in a direction away from the side surface of the first metal layer.

The display module may further include a light transmission layer surrounding the metal layer and the light absorption layer.

The metal layer and the light absorption layer may be respectively provided as a plurality of metal layers and a plurality of light absorption layers, and the plurality of metal layers and the plurality of light absorption layers may be alternately stacked.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a block diagram of an electronic device according to an embodiment;

FIGS. 2, 3, and 4, are perspective views of electronic devices according to various embodiments;

FIG. 5 is a perspective view schematically illustrating an electronic device according to an embodiment;

FIG. 6 is an exploded perspective view schematically illustrating the electronic device of FIG. 5;

FIG. 7A is a plan view schematically illustrating a portion of the display apparatus of FIG. 6;

FIG. 7B is a cross-sectional view schematically illustrating a portion of the display apparatus of FIG. 7A;

FIG. 8 is a plan view schematically illustrating a portion of the display apparatus of FIG. 6;

FIG. 9 is a circuit diagram schematically illustrating a subpixel circuit of a subpixel disposed in a display area of FIG. 8;

FIG. 10 is a cross-sectional view schematically illustrating a portion of the display apparatus of FIG. 6;

FIG. 11 is a cross-sectional view of the display apparatus taken along line B-B' of FIG. 8;

FIGS. 12A to 12H are cross-sectional views schematically illustrating a manufacturing order of a display panel of FIG. 11;

FIG. 13A is a cross-sectional view schematically illustrating a metal layer of a display panel according to an embodiment;

FIG. 13B is a cross-sectional view schematically illustrating a metal layer of a display panel according to an embodiment;

FIG. 14A is a cross-sectional view schematically illustrating a metal layer and a light absorption layer of a display panel according to an embodiment;

FIG. 14B is a cross-sectional view schematically illustrating a metal layer and a light absorption layer of a display panel according to an embodiment;

FIG. 15A is a cross-sectional view schematically illustrating a metal layer and a light absorption layer of a display panel according to an embodiment; and

FIG. 15B is a cross-sectional view schematically illustrating a metal layer and a light absorption layer of a display panel according to an embodiment.

### DETAILED DESCRIPTION

Reference will now be made in detail to various embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments are described below, by referring to the figures, to explain aspects of the present description. As used herein, the term "and/or" includes any and all combinations of one or more of the associated listed items. Throughout the disclosure, the expression "at least one of a, b and c" indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and methods of achieving them will become apparent with reference to the embodiments described below in detail together with the drawings. However, the disclosure is not necessarily limited to the embodiments described below and may be implemented in various forms.

Hereinafter, embodiments will be described in detail with reference to the accompanying drawings, and in the following description, like reference numerals may denote like elements and to the extent that an element is not described in detail with respect to this figure, it may be understood that the element is at least similar to a corresponding element that has been described elsewhere within the present disclosure.

It will be understood that although terms such as "first" and "second" may be used herein to describe various elements, these elements should not necessarily be limited by these terms and these terms are used to distinguish one element from another element.

As used herein, the singular forms "a," "an," and "the" are intended to include the plural forms as well, unless the context clearly indicates otherwise.

It will be understood that terms such as "comprise," "include," and "have" used herein specify the presence of stated features or elements, but do not preclude the presence or addition of one or more other features or elements.

It will be understood that when a layer, region, or component is referred to as being "on" another layer, region, or component, it may be "directly on" the other layer, region, or component or may be "indirectly on" the other layer, region, or component with one or more intervening layers, regions, or components therebetween.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Also, herein, the x axis, the y axis, and the z axis are not necessarily limited to three axes of the Cartesian coordinate system and may be interpreted in a broader sense. For example, the x axis, the y axis, and the z axis may be perpendicular to one another or may represent different directions that are not perpendicular to one another.

When a certain embodiment may be implemented differently, a particular process order may be performed differently from the described order. For example, two consecutively described processes may be performed substantially at the same time or performed in an order opposite to the described order.

Embodiments of the present disclosure relate to a specialized display panel designed to increase privacy and viewing quality by controlling the direction and visibility of light emitted therefrom. The display panel includes a multilayer structure, including a substrate, a display layer, which may include light-emitting diodes (OLEDs), and an encapsulation layer to protect the display components. Over these foundational layers, a uniquely structured metal layer is applied, and on top of the metal layer, a light absorption layer is disposed.

The metal and light absorption layers are formed and positioned according to a novel arrangement. The metal layer includes multiple sub-layers, with at least one having a tip portion that protrudes further than others. This configuration ensures precise alignment and positioning of the overlying light absorption layer. Some of these metal sub-layers also have inclined surfaces, and in certain embodiments, they include different materials to tailor their optical and structural properties.

By incorporating these specialized layers, embodiments of the present disclosure may enable control over the directions in which light can pass through or be emitted from the display. This results in a screen that limits visibility from side angles, which both enhances user privacy and reduces the likelihood of screen reflections being visible in nearby reflective surfaces, such as windows or eyeglasses.

This optical control mechanism may be particularly beneficial in mobile or wearable devices, vehicles, and other electronic devices where privacy and reduced glare are desired. The metal and absorption layers may be patterned in a specific orientation across the display area, such as in alternating or stacked configurations, to achieve the desired light management effects. Overall, mechanical, optical, and electronic design elements are incorporated to increase the functionality and user experience of modern display technologies.

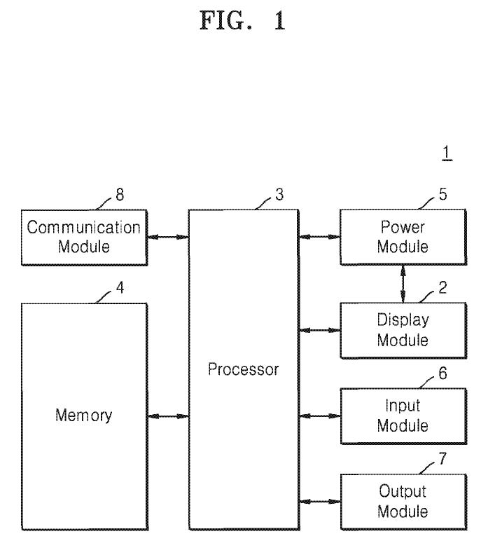

FIG. 1 is a block diagram of an electronic device according to an embodiment.

Referring to FIG. 1, an electronic device 1, according to an embodiment, may include a display module 2, a processor 3, a memory 4, and a power module 5. The display module 2 may include a display panel or a display apparatus, which will be described below.

The processor 3 may include at least one of a central processing unit (CPU), an application processor (AP), a graphic processing unit (GPU), a communication processor (CP), an image signal processor (ISP), and a controller. In an embodiment, the processor 3 may be divided into two or more processors from a functional or structural viewpoint. For example, the processor 3 may include a main processor in the form of a first driving chip including a CPU, and an auxiliary processor in the form of a second driving chip including a controller that receives an image signal from the main processor and processes the image signal in accordance with the interface specifications of the display module 2.

The memory 4 may include at least one of a nonvolatile memory and a volatile memory. The memory 4 may store data information necessary for the operation of the processor 3 or the display module 2. When the processor 3 executes an application stored in the memory 4, an image data signal and/or an input control signal may be transmitted to the display module 2 and the display module 2 may process the received signal and output image information through a display screen.

The power module 5 may include a power supply module such as a power adapter or a battery device, and a power conversion module that converts the power supplied by the power supply module to generate power necessary for the operation of the electronic device 1. The power conversion by the power conversion module may include, but is not necessarily limited to, DC-DC conversion, AC-DC conversion, and DC-AC conversion.

The electronic device 1 may further include an input module 6, an output module 7 (other than one that displays an image), and/or a communication module 8, such as a radio transceiver and associated hardware.

The input module 6 may provide input information to the processor 3 and/or the display module 2. The input module 6 may include various sensor modules as well as physical buttons, a keyboard, and a microphone. Examples of the sensor modules may include not only a touch sensor, a pressure sensor, a distance sensor, a position sensor, a digitizer, a motion recognition sensor, a camera sensor, a light receiving sensor, a photoelectric conversion sensor, and a temperature sensor but also biometric sensors such as a blood pressure sensor, a blood sugar sensor, an electrocardiogram sensor, and a heart rate sensor.

The output module 7 may receive information other than the image received from the processor 3 and provide the information to the user. Examples of the output module 7 may include an audio module, a haptic module, and a light emitting module (such as an indicator light) and may include other functional modules unique to the electronic device 1(e.g., a cooling module of a refrigerator).

The communication module 8 may be a module managing transmission/reception of information between the electronic device 1 and an external device and may include a receiver and a transmitter. The communication module 8 may include various wireless communication modules such as a mobile communication module, a WiFi module, and a Bluetooth module or various wired communication modules.

At least one of the components of the electronic device 1 described above may be included in a display apparatus, according to embodiments described below. Also, some of the individual modules functionally included in one module may be included in the display apparatus, and some others thereof may be provided separately from the display apparatus. For example, the display apparatus may include the display module 2, and the processor 3, the memory 4, and the power module 5 may be provided in the form of other devices in the electronic device 1 that is not the display apparatus. As an example, the power module 5 may be disposed in the display apparatus and may supply power to the processor 3 and the memory 4 provided in the electronic device 1 that are not the display apparatus; however, the disclosure is not necessarily limited thereto.

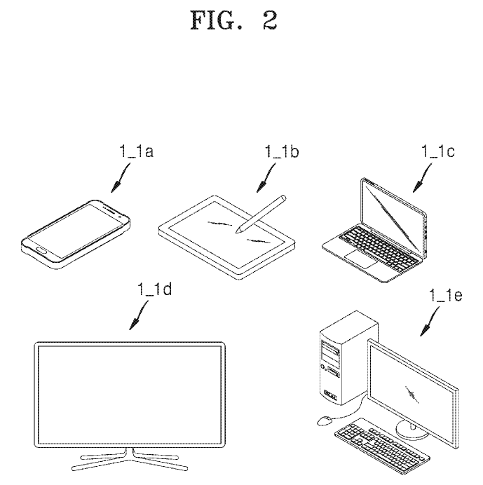

FIGS. 2 to 4 are schematic diagrams of electronic devices according to various embodiments. FIGS. 2 to 4 illustrate examples of various electronic devices including display apparatuses according to embodiments.

FIG. 2 illustrates a smart phone 1_1a, a tablet computer 1_1b, a laptop/notebook computer 1_1c, a television (TV) 1_1d, and a desktop computer 1_1e as examples of the electronic devices. The smart phone 1_1a may include an input module such as a touch sensor and a communication module in addition to the display module. The smart phone 1_1a may process information received through the communication module or other input modules and display the processed information through the display module of the display apparatus.

Similarly to the smart phone 1_1a, the tablet computer 1_1b, the laptop/notebook computer 1_1c, the TV 1_1d, and the desktop computer 1_1e may also include a display module and an input module and may further a communication module in some cases.

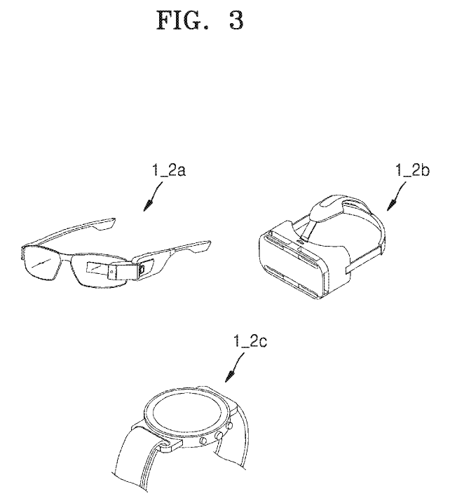

FIG. 3 illustrates a case where an electronic devices including a display module is a wearable electronic devices. The wearable electronic devices may be smart glasses 1_2a, a head-mounted display 1_2b, a smart watch 1_2c, or the like.

The smart glasses 1_2a and the head-mounted display 1_2b may include a display module that emits a display image and a reflector that reflects an emitted display screen and provides the same to the user's eyes, thereby providing a virtual reality or augmented reality screen to the user.

The smart watch 1_2c may include a biometric sensor as an input device and may provide biometric information recognized by the biometric sensor to the user through a display module.

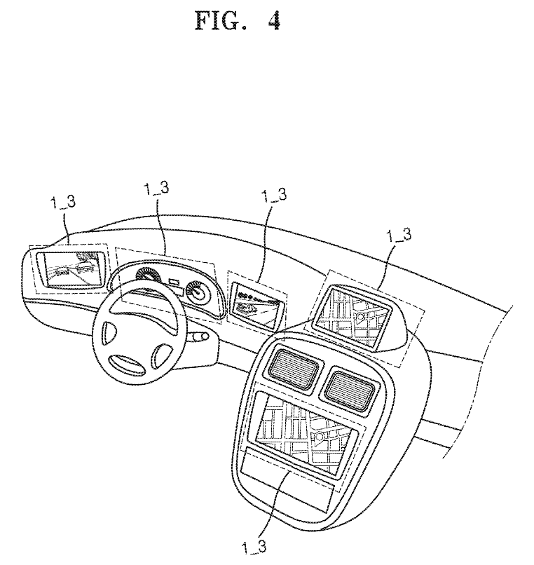

FIG. 4 illustrates a case where an electronic devices including a display module is applied to a vehicle. For example, an electronic devices 1_3 may be applied to a dashboard, a center fascia, or the like of a vehicle or may be applied to a center information display (CID) disposed on a dashboard of a vehicle, a room mirror display replacing a side mirror, or the like.

The electronic devices to which the display apparatus, according to embodiments, is applied may include not only apparatuses that mainly display screens, such as digital billboards, electronic display boards, and portable game consoles, but also various home appliances that display information through display modules, such as refrigerators, washing machines, dryers, air conditioners, and robotic vacuum cleaners. Also, when the display module has a function of transmitting light, it may be applied to electronic devices such as a smart window or a transparent display apparatus that displays a background and display images together. The types of the electronic devices, according to embodiments, are not necessarily limited to the above illustration, and the disclosure may also be applied to various other electronic devices.

Hereinafter, for convenience of description, a detailed description will be given mainly of a case where the electronic devices 1 is a smart phone.

Thus, according to the above, display devices in accordance with exemplary embodiments of the present disclosure may be included within a myriad of electronic devices, such as those discussed above and other.

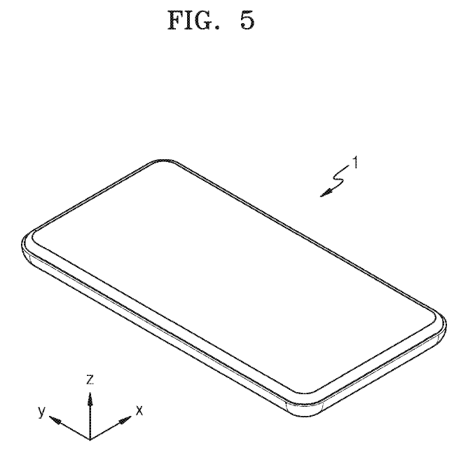

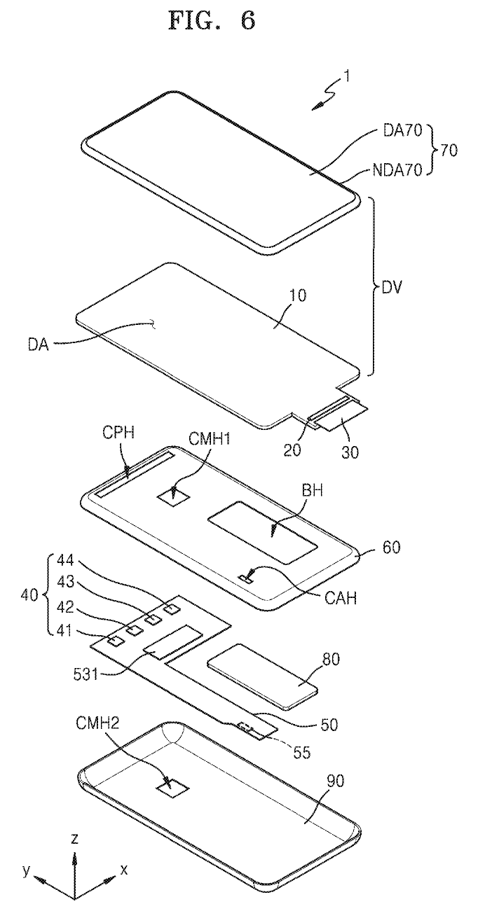

FIG. 5 is a perspective view schematically illustrating an electronic devices according to an embodiment. FIG. 6 is an exploded perspective view schematically illustrating the electronic devices of FIG. 5.

Referring to FIGS. 5 and 6, an electronic devices 1 may include a display apparatus DV, a component 40, a bracket 60, a main circuit board 50, a battery 80, and/or a lower cover 90. The display apparatus DV may include a cover window 70, a display panel 10, a data driver 20, and a display circuit board 30.

In a plan view herein, "left," "right," "up," and "down" may refer to directions when viewing the display panel 10 in a vertical direction of the display panel 10. For example, "left" may refer to the -x direction, "right" may refer to the +x direction, "up" may refer to the +y direction, and "down" may refer to the -y direction.

The electronic devices 1 may appear to have a substantially rectangular shape in the plan view. For example, the electronic devices 1 may appear to have a substantially rectangular shape having a pair of short side extending primarily in the x-axis direction and a pair of long side extending primarily in the y-axis direction on the xy plane as illustrated in FIG. 5. In this case, the corner where the short side in the x-axis direction and the long side in the y-axis direction meet each other may form a right angle or may have a round shape to have a certain curvature. Also, in the plan view, the electronic devices 1 may have a polygonal shape other than a rectangular shape or may have an elliptical shape, an atypical shape, or the like.

The cover window 70 may be disposed on the display panel 10 so as to cover the upper surface of the display panel 10. The cover window 70 may protect the upper surface of the display panel 10.

The cover window 70 may include a light-transmitting cover unit DA70 corresponding to the display panel 10 and a light-blocking cover unit NDA70 surrounding the light-transmitting cover unit DA70. The light-blocking cover unit NDA70 may include an opaque material (e.g., a colored opaque material) that blocks light. The light-blocking cover unit NDA70 may include a pattern that may be shown to the user in the case of not displaying an image.

The display panel 10 may be disposed under the cover window 70. The display panel 10 may overlap the light-transmitting cover unit DA70 of the cover window 70. The display panel 10 may include a display area DA. The display area DA may be an area where an image is displayed, and the display area DA may include an area (also referred to as a component area) that transmits light emitted from the component 40 disposed under the display panel 10. The component 40 may include a sensor or a camera that uses visible light, infrared light, or sound.

The display panel 10 may be a light emitting display panel including a light emitting diode. The light emitting diode may be an organic light emitting diode including an emission layer or may be an inorganic light emitting diode including an inorganic material. In the case of the inorganic light emitting diode, it may include a PN junction diode including inorganic semiconductor-based materials. When a forward voltage is applied to the PN junction diode, holes and electrons may be injected thereinto and energy generated by the recombination of the holes and electrons may be converted into light energy to emit light of a certain color. The inorganic light emitting diode may have a width of several micrometers to several hundred micrometers. The inorganic light emitting diode may be referred to as a micro LED.

The display panel 10 may be a rigid display panel that is rigid and thus is not easily bent or may be a flexible display panel that is flexible and thus may be easily bent, folded, or rolled to at least a noticeable degree without cracking or otherwise sustaining damage thereto. For example, the display panel 10 may be a foldable display panel that may be folded and unfolded, may be a curved display panel with a curved display surface, may be a bent display panel with an area other than a display surface bent, may be a rollable display panel that may be rolled or unrolled, or may be a stretchable display panel that may be stretched.

The display panel 10 may be a transparent display panel that is transparently implemented such that an object or background disposed on the lower surface of the display panel 10 may be viewed from the upper surface of the display panel 10. Alternatively, the display panel 10 may be a reflective display panel that may reflect an object or background on the upper surface of the display panel 10.

The data driver 20 may be mounted on the display panel 10 in the form of an integrated circuit (IC). However, the disclosure is not necessarily limited thereto, and for example, the data driver 20 may be mounted on the display circuit board 30.

The display circuit board 30 may be attached to one side of the display panel 10. The display circuit board 30 may be a flexible printed circuit board (FPCB) that may be bent, may be a rigid printed circuit board (PCB) that is rigid and thus is not easily bent, or may be a composite printed circuit board including both a rigid printed circuit board and an FPCB. In an embodiment, when the display panel 10 includes a touch screen layer, a touch sensor driver may be mounted on the display circuit board 30. The touch sensor driver may be formed as an integrated circuit. The touch sensor driver may be electrically connected to touch electrodes of a touch screen layer of the display panel 10 through the display circuit board 30.

When the display panel 10 includes a touch screen layer, the touch screen layer may detect a user's touch input by using at least one of various touch methods such as a resistive method and a capacitive method. When the touch screen layer of the display panel 10 detects a user's touch input by the capacitive method, the touch sensor driver may apply driving signals to driving electrodes among the touch electrodes and detect voltages charged in mutual electrostatic capacitances (hereinafter referred to as "mutual capacitances") between driving electrodes and sensing electrodes through sensing electrodes among the touch electrodes, thereby determining whether a user's touch has occurred.

The user's touch may include a contact touch and a proximity touch. The contact touch may mean that a user's finger or an object such as a pen directly contacts the cover window 70 disposed on the touch screen layer. The proximity touch may mean that a user's finger or an object such as a pen is located close to and apart from the cover window 70, such as hovering above the display surface without contact. The touch sensor driver may transmit sensor data to a main processor according to the detected voltages, and the main processor may calculate touch coordinates of the touch input by analyzing the sensor data. For the convenience of description, the following description will focus on a case where the display panel 10 does not include a touch screen layer. However, the display panel 10 may alternatively include a touch screen layer without departing from the spirit and scope of the present disclosure.

A controller for supplying driving voltages for driving pixels and a gate driver of the display panel 10, and/or the data driver 20 may be disposed on the display circuit board 30.

The bracket 60 for supporting the display panel 10 may be disposed under the display panel 10. The bracket 60 may include plastic, metal, or both plastic and metal. The bracket 60 may include a first camera hole CMH1 into which a camera device 531 is inserted, a battery hole BH in which the battery 80 is disposed, a cable hole CAH through which a cable connected to the display circuit board 30 passes, and a component hole CPH corresponding to components 40. The component hole CPH may overlap the components 40 of the main circuit board 50 when viewed in a third direction (e.g., z-axis direction). For reference, the display area DA of the display panel 10 may overlap the components 40 of the main circuit board 50 when viewed in the third direction (e.g., z-axis direction). However, when necessary, the bracket 60 might not include the component hole CPH.

The components 40 included in the electronic devices 1 may include a first component 41, a second component 42, a third component 43, and a fourth component 44 that overlap the display panel 10. Each of the first component 41, the second component 42, the third component 43, and the fourth component 44 may include at least one of a proximity sensor, an illumination sensor, an iris sensor, a face recognition sensor, and a camera (or an image sensor). The proximity sensor using infrared rays may detect an object located close to the upper surface of the electronic devices 1, and the illumination sensor may sense the brightness of light incident on the upper surface of the electronic devices 1. Also, the iris sensor may photograph a person's iris located over the upper surface of the electronic devices 1, and the camera may obtain image data about an object disposed on the upper surface of the electronic devices 1. However, the components 40 are not necessarily limited to a proximity sensor, an illumination sensor, an iris sensor, a face recognition sensor, and/or a camera and may include other sensors.

The main circuit board 50 and the battery 80 may be disposed under the bracket 60. The main circuit board 50 may be a rigid printed circuit board or an FPCB.

The main circuit board 50 may include a main processor, a camera device 531, a main connector 55, and components 40. The main processor may include an integrated circuit. When necessary, the electronic devices 1 may also include a camera device disposed on the lower surface of the main circuit board 50, as well as the camera device 531 disposed on the upper surface of the main circuit board 50. Each of the main processor and the main connector 55 may be disposed on any one of the upper surface and the lower surface of the main circuit board 50. The main circuit board 50 may be electrically connected to the display circuit board 30 through the main connector 55 or the like.

The main processor may control all functions of the electronic devices 1. For example, the main processor may output digital video data to the data driver 20 through the display circuit board 30 such that the display panel 10 may display an image. The main processor may receive sensing data from the touch sensor driver. The main processor may determine whether there is a user touch based on the sensing data and execute an operation corresponding to the user's direct touch or proximity touch. The main processor may be an application processor, a central processing unit, or a system chip including an integrated circuit.

The camera device 531 may process an image frame such as a still image or a moving image obtained by an image sensor in a camera mode and output the processed image frame to the main processor. The camera device 531 may include at least one of a camera sensor (e.g., CCD or CMOS), a photo sensor (or an image sensor), and a laser sensor.

A cable passing through the cable hole CAH of the bracket 60 may be connected to the main connector 55, and the main circuit board 50 may be electrically connected to the display circuit board 30 through the cable.

The electronic devices 1 may include a wireless communicator, an input unit, a sensor unit, an output unit, an interface unit, a memory, and/or a power supply unit in addition to the main processor.

The wireless communicator may include at least one of a broadcast receiving module, a mobile communication module, a wireless Internet module, a short-range communication module, and a position information module.

The broadcast receiving module may receive broadcast signals and/or broadcast-related information from an external broadcast management server through broadcast channels. The broadcast channels may include satellite channels and terrestrial channels.

The mobile communication module may transmit/receive wireless signals to/from at least one of a base station, an external terminal, and a server in a mobile communication network established according to technology standards or communication methods for mobile communication (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signals may include various forms of data according to voice call signals, video call signals, or text/multimedia message transmission/reception.

The wireless Internet module may refer to a module for wireless Internet access. The wireless Internet module may be configured to transmit/receive wireless signals in a communication network according to wireless Internet technologies. The wireless Internet technologies may be, for example, Wireless LAN (WLAN), Wireless Fidelity (WiFi), WiFi Direct, and/or Digital Living Network Alliance (DLNA).

The short-range communication module may be for short-range communication and may support short-range communication by using at least one of Bluetooth™, Radio Frequency Identification (RFID), Infrared Data Association (IrDA), Ultra Wideband (UWB), ZigBee, Near Field Communication (NFC), Wireless Fidelity (WiFi), WiFi Direct, and Wireless Universal Serial Bus (Wireless USB) technologies. The short-range communication module may support wireless communication between the electronic devices 1 and a wireless communication system, between the electronic devices 1 and another electronic devices, or between the electronic devices 1 and a network in which another electronic devices (or an external server) is located, through a short-range wireless communication network (Wireless Area Network). The short-range wireless communication network may be a short-range wireless personal area network (Wireless Personal Area Network). The other electronic devices may be a wearable device capable of exchanging data (or capable of interoperating) with the electronic devices 1.

The position information module may be a module for obtaining the position of the electronic devices 1 and may include a Global Positioning System (GPS) module or a Wireless Fidelity (WiFi) module.

The input unit may include an image input unit such as a camera device 531 for inputting an image signal, an audio input unit such as a microphone for inputting an audio signal, and an input device for receiving information from the user. The camera device 531 may process an image frame such as a still image or a moving image obtained by an image sensor in a video call mode or a photographing mode. The processed image frame may be displayed on the display panel 10 or stored in the memory. The microphone may process an external audio signal into electrical voice data. The processed voice data may be variously used depending on the functions performed (or the applications executed) in the electronic devices 1.

The main processor may control an operation of the electronic devices 1 to correspond to information input through the input device. The input device may include a mechanical input unit or a touch input unit such as a button, a dome switch, a jog wheel, or a jog switch located on the rear surface or side surface of the electronic devices 1. The touch input unit may include a touch screen layer of the display panel 10.

The sensor unit may include one or more sensors that sense at least one of information in the electronic devices 1, information about the surrounding environment surrounding the electronic devices 1, and user information and generate a sensing signal corresponding thereto. The main processor may control the driving or operation of the electronic devices 1 based on the sensing signal or perform data processing, functions, or operations related to the application installed on the electronic devices 1. The sensor unit may be a proximity sensor, an illumination sensor, or a face recognition sensor as described above with respect to the component 40. Also, the sensor unit may include an acceleration sensor, a magnetic sensor, a gravity sensor (G-sensor), a gyroscope sensor, a motion sensor, an RGB sensor, an infrared sensor (IR sensor), a fingerprint recognition sensor (finger scan sensor), an ultrasonic sensor, an optical sensor, and/or a battery gauge. In addition, the sensor unit may include an environmental sensor or a chemical sensor. The environmental sensor may be, for example, a barometer, a hygrometer, a thermometer, a radiation detection sensor, a heat detection sensor, and/or a gas detection sensor. The chemical sensor may be, for example, an electronic nose, a healthcare sensor, and/or a biometric sensor.

The output unit may be for generating an output related to visual, auditory or tactile sensation and may include at least one of a display panel 10, an audio output unit, a haptic module, and a light output unit.

The display panel 10 may display (e.g., output) information processed in the electronic devices 1. For example, the display panel 10 may display execution screen information of an application driven in the electronic devices 1, display a user interface (UI) according to the execution screen information, or display graphical user interface (GUI) information. The display panel 10 may include a display layer for displaying an image and a touch screen layer for detecting a user's touch input. Accordingly, the display panel 10 may function as one of input devices providing an input interface between the electronic devices 1 and the user and may simultaneously function as one of output units providing an output interface between the electronic devices 1 and the user.

The audio output unit may output audio data received from the wireless communicator or stored in the memory, in a call signal reception mode, a call mode, a recording mode, a voice recognition mode, and/or a broadcast reception mode. The audio output unit may also output an audio signal related to a function performed in the electronic devices 1 (e.g., a call signal reception sound or a message reception sound). The audio output unit may include a receiver and a speaker. At least one of the receiver and the speaker may be an audio generating device that is attached to the lower portion of the display panel 10 and vibrates the display panel 10 to output audio. The audio generating device may be a piezoelectric element or a piezoelectric actuator that contracts and expands according to an electric signal or may be an exciter that vibrates the display panel 10 by generating a magnetic force by using a voice coil.

The haptic module may generate various haptic effects that the user may feel. The haptic module may provide a vibration as a haptic effect to the user. The haptic module not only may transmit a haptic effect through direct contact but also may be implemented such that the user may feel a haptic effect through a muscle sense of the fingers, arms, or the like.

The light output unit may output a signal for notifying the occurrence of an event by using light of a light source. Examples of the event occurring in the electronic devices 1 may include message reception, call signal reception, missed call, alarm, schedule notification, email reception, and/or information reception through an application. The signal output from the light output unit may be implemented by the electronic devices 1 emitting light of a single color or a plurality of colors from the front surface or rear surface. The signal output may be terminated when the electronic devices 1 detects the user's identification of an event.

The interface unit may function as a path for various types of external devices connected to the electronic devices 1. The interface unit may include at least one of a wired/wireless headset port, an external charger port, a wired/wireless data port, a memory card port, a port for connecting a device including an identification module, an audio input/output (I/O) port, a video input/output (I/O) port, and an earphone port. When an external device is connected to the interface unit, the electronic devices 1 may perform suitable control related to the connected external device.

The memory may store data for supporting various functions of the electronic devices 1. The memory may store a plurality of applications (application programs) driven in the electronic devices 1, data for the operation of the electronic devices 1, and/or instructions. At least some of the plurality of applications may be downloaded from an external server through wireless communication. The memory may store an application for the operation of the main processor and may temporarily store input/output data such as a phonebook, a message, a still image, and/or a moving image. Also, the memory may store haptic data for various patterns of vibration provided to the haptic module and audio data about various sounds provided to the audio output unit.

The memory may include at least one type of storage medium from among flash memory, hard disk, solid state disk (SSD), silicon disk drive (SDD), multimedia card micro, card type memory (e.g., SD and XD memories), random-access memory (RAM), static random-access memory (SRAM), read-only memory (ROM), electronically erasable programmable read-only memory (EEPROM), programmable read-only memory (PROM), magnetic memory, magnetic disk, and optical disk.

Under the control by the main processor, the power supply unit may receive external power and/or internal power and supply the power to each of the components 40 included in the electronic devices 1. The power supply unit may include the battery 80. Also, the power supply unit may include a connection port, and the connection port may be an example of the interface unit to which an external charger supplying power for charging the battery 80 is electrically connected. Alternatively, the power supply unit may allow the battery 80 to be wirelessly charged. The battery 80 may be disposed so as not to overlap the main circuit board 50 in the third direction (e.g., z-axis direction). The battery 80 may overlap the battery hole BH of the bracket 60.

The lower cover 90 may form the external shape of the electronic devices 1 and may include an opening that exposes a portion of the display panel 10. The lower cover 90 may have an open shape corresponding to the display panel 10 and may be fastened to the display panel 10. The lower cover 90 may be located on the opposite side of the cover window 70 with the display panel 10 therebetween. The lower cover 90 may be disposed under the main circuit board 50 and the battery 80. The lower cover 90 may be fastened and fixed to the bracket 60. The lower cover 90 may form the external shape of the lower surface of the electronic devices 1. The lower cover 90 may include plastic, metal, or both plastic and metal.

A second camera hole CMH2 may be formed in the lower cover 90 to expose the lower surface of the camera device 531. The position of the camera device 531 and the positions of the first camera hole CMH1 and the second camera hole CMH2 corresponding to the camera device 531 are not necessarily limited to those illustrated in FIG. 6 and may be variously modified.

Thus, the arrangement of the display apparatus may include the display panel, cover window, data driver, and circuit board, and may support components like the bracket, circuit board, battery, and sensors. Capabilities such as touch input detection, image display and capture, audio output, and wireless communication, may all be integrated within a layered hardware configuration designed for flexibility and functionality.

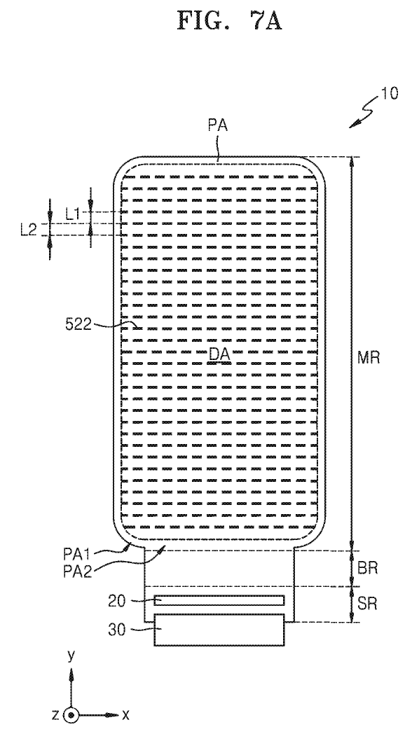

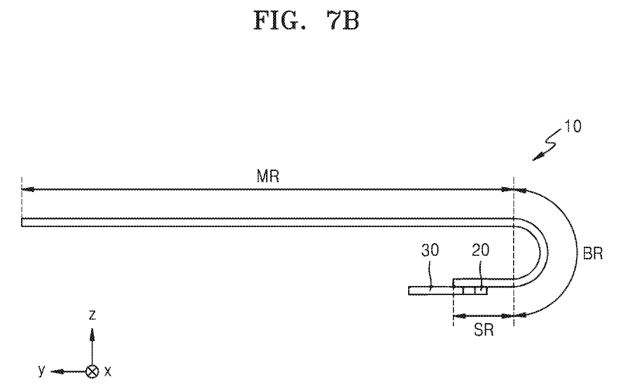

FIG. 7A is a plan view schematically illustrating a portion of the display apparatus of FIG. 6. FIG. 7B is a cross-sectional view schematically illustrating a portion of the display apparatus of FIG. 7A. The electronic devices 1 described above may include a portion of the display apparatus illustrated in FIGS. 7A and 7B.

Referring to FIGS. 7A and 7B, the display apparatus may include a cover window, a display panel 10, a data driver 20, and a display circuit board 30.

The display panel 10 may include a display area DA and a peripheral area PA outside the display area DA. The display area DA may be an area for displaying an image, and a plurality of subpixels may be disposed in the display area DA. For example, the display area DA may have any of various shapes such as a circular shape, an elliptical shape, a polygonal shape, and a particular figure shape. FIG. 7A illustrates that the display area DA has a substantially rectangular shape with rounded corners.

The peripheral area PA may be located outside the display area DA. The peripheral area PA may include a first peripheral area PA1 surrounding at least a portion of the display area DA and a second peripheral area PA2 located under the display area DA and extending in the first direction (e.g., x-axis direction). The width of the second peripheral area PA2 in the first direction (e.g., x-axis direction) may be less than the width of the display area DA. Through this structure, at least a portion of the second peripheral area PA2 may be easily bent to at least a noticeable degree without cracking or otherwise sustaining damage thereto.

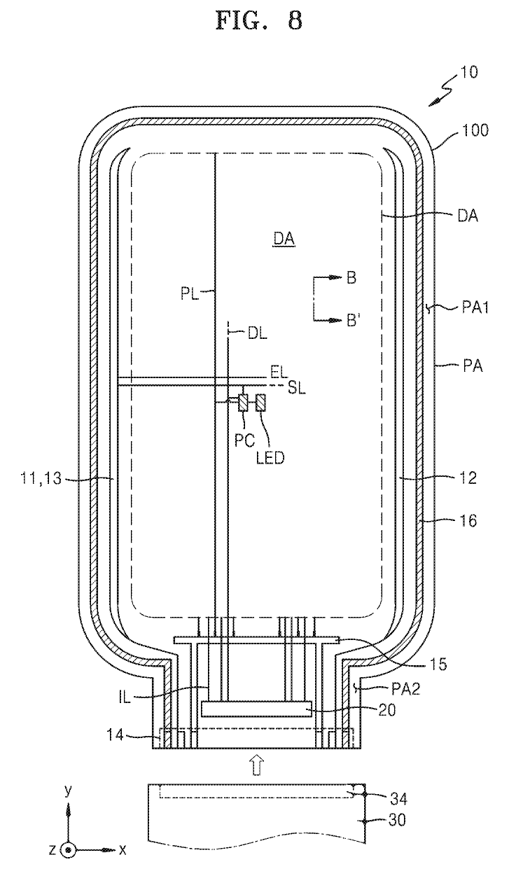

The planar shape of the display panel 10 illustrated in FIG. 7A may be substantially the same as the shape of a substrate 100 (see FIG. 8) included in the display panel 10. When the display panel 10 includes the display area DA and the peripheral area PA outside the display area DA, it may be considered that the substrate 100 includes the display area DA and the peripheral area PA outside the display area DA. Hereinafter, for convenience, it will be described that the substrate 100 includes the display area DA and the peripheral area PA.

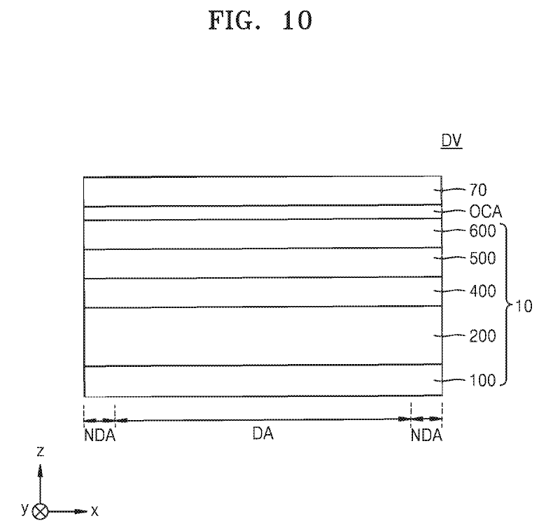

The display panel 10 may include a main region MR, a bending region BR outside the main region MR, and a sub-region SR spaced apart from the main region MR with the bending region BR therebetween. The main region MR may be disposed on one side of the bending region BR, and the sub-region SR may be disposed on the other side of the bending region BR. The display panel 10 may be bent in the bending region BR as illustrated in FIG. 7B, and at least a portion of the sub-region SR may overlap the main region MR when viewed in the third direction (e.g., z-axis direction). Although FIG. 7B illustrates that the display panel 10 is bent, the disclosure is not necessarily limited thereto. For example, the display panel 10 may be a foldable display panel, and in this case, the display panel 10 may be bent in the display area DA around a bending axis intersecting the display area DA. However, when necessary, the display panel 10 might not be bent. The sub-region SR may be a non-display area NDA (see FIG. 10).

A data driver 20 may be disposed in the sub-region SR of the display panel 10. The data driver 20 may be disposed on the display panel 10 in the form of an integrated circuit (IC). For example, the data driver 20 may be a data driving integrated circuit that generates a data signal.

A display circuit board 30 may be attached to an end portion of the sub-region SR of the display panel 10. The display circuit board 30 may be electrically connected to the data driver 20 or the like through a pad of the sub-region SR of the display panel 10.

A light control layer 500 (see FIG. 10) may be disposed in the display area DA. In this case, a metal layer and a light absorption layer 522 of a light control layer 500 may be in a line shape and may be provided as a plurality of metal layers and a plurality of light absorption layers 522 in the display area DA. The lengthwise direction of the metal layer and the light absorption layer 522 may be various directions. For example, the lengthwise direction of the metal layer and the light absorption layer 522 may be the direction of extension of a short side or a long side of the display area DA. In an embodiment, the lengthwise direction of the metal layer and the light absorption layer 522 may be disposed in the display area DA so as to form an acute angle with respect to one side of the display area DA. When the planar shape of the display area DA is polygonal other than tetragonal, the metal layer and the light absorption layer 522 may be disposed such that the lengthwise direction of the metal layer and the light absorption layer 522 is parallel to or forms a certain angle with respect to one side of the planar shape of the display area DA. In an embodiment, when the planar shape of the display area DA is circular, the metal layer and the light absorption layer 522 may be disposed in the display area DA such that the lengthwise direction of the metal layer and the light absorption layer 522 is parallel to or forms a certain angle with respect to one of the diameters of the planar shape of the display area DA. In an embodiment, when the planar shape of the display area DA is elliptical, the metal layer and the light absorption layer 522 may be disposed in the display area DA such that the lengthwise direction of the metal layer and the light absorption layer 522 is parallel to or forms a certain angle with respect to a major axis of the planar shape of the display area DA. In an embodiment, when the planar shape of the display area DA is atypical, such as a shape other than polygonal, circular, and elliptical, the metal layer and the light absorption layer 522 may be disposed in a line shape to intersect the internal space of the display area DA. In the above case, all of the shortest distances between adjacent light absorption layers 522 among the plurality of light absorption layers 522 may be equal to each other. In an embodiment, a distance between adjacent light absorption layers 522 among the plurality of light absorption layers 522 may be different from another distance between the adjacent light absorption layers 522 among the plurality of light absorption layers 522. For example, unlike in FIG. 7A, a first distance L1 between one of the plurality of adjacent light absorption layers 522 and another of the plurality of light absorption layers 522 may be different from a second distance L2 between another of the plurality of adjacent light absorption layers 522 and another of the plurality of light absorption layers 522. The relationship between the plurality of light absorption layers 522 may be similarly applied to the relationship between the plurality of metal layers. The metal layer and the light absorption layer 522 may be disposed only in a portion of the display area DA. For example, in FIG. 7A, the metal layer and the light absorption layer 522 may be disposed only on the left, right, upper, or lower side of the display area DA with respect to the center of the display area DA. For convenience of description, the following description will focus on a case where the metal layer and the light absorption layer 522 are perpendicular to a long side of the display area DA and parallel to a short side thereof, and the distance between adjacent light absorption layers 522 and the distance between adjacent metal layers are equal to each other. In FIG. 7A, the light absorption layer 522 is represented as a dotted line; however, the light absorption layer 522 may be in the form of a line connecting one of the long sides of the display area DA of FIG. 7A to another one thereof.

The light control layer 500 described above may block some of the propagation directions of light emitted from the subpixel disposed in the display area DA, thereby preventing an image of the display panel 10 from being viewed at a certain angle with the surface of the display panel 10. Accordingly, the display panel 10 not only may protect the privacy of the user but also may reduce an image of the display panel 10 from being reflected on an object (e.g., a car window or glasses) located at a certain position with respect to the display panel 10.

FIG. 8 is a plan view schematically illustrating a portion of the display apparatus of FIG. 6.

Referring to FIG. 8, the display panel 10 may include a substrate 100. Various components included in the display panel 10 may be disposed on the substrate 100.

The substrate 100 may include glass, ceramic, metal, or polymer resin. The substrate 100 may include a polymer resin such as polyethersulphone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multilayer structure including two layers including the polymer resin and an inorganic layer disposed between the two layers. Alternatively, the substrate 100 may have a structure in which layers including the polymer resin and inorganic layers are alternately stacked. The inorganic layer may include, for example, silicon oxide, silicon nitride, or silicon oxynitride.

Subpixels may be disposed in the display area DA, and the display area DA may provide an image by using light emitted from the subpixels. Each subpixel may include a light emitting diode LED that is a display element, and the light emitting diode LED may be electrically connected to a subpixel circuit PC. The subpixel circuit PC and the light emitting diode LED may be disposed in the display area DA. For convenience, FIG. 8 illustrates that the subpixel circuit PC and the light emitting diode LED are located in parallel; however, the subpixel circuit PC and the light emitting diode LED may at least partially overlap each other. For example, the light emitting diode LED may be disposed on the subpixel circuit PC.

A gate driving circuit, a pad 14, a first power supply line 15, and a second power supply line 16 may be disposed in the peripheral area PA. The gate driving circuit may include, for example, a first scan driving circuit 11, a second scan driving circuit 12, and/or an emission control driving circuit 13.

The first scan driving circuit 11 may provide a scan signal to the subpixel circuit PC through a scan line SL. The second scan driving circuit 12 may be disposed on the opposite side of the first scan driving circuit 11 with the display area DA therebetween. Some of the subpixel circuits PC disposed in the display area DA may be electrically connected to the first scan driving circuit 11, and the others may be connected to the second scan driving circuit 12. However, in some cases, the second scan driving circuit 12 may be omitted.

Like the first scan driving circuit 11, the emission control driving circuit 13 may be disposed on one side of the display area DA. The emission control driving circuit 13 may provide an emission control signal to the subpixel circuit PC through an emission control line EL. FIG. 8 illustrates that the emission control driving circuit 13 is disposed only on one side of the display area DA; however, the disclosure is not necessarily limited thereto. For example, the display panel 10 may include emission control driving circuits 13 disposed on one side and the other side of the display area DA. Alternatively, the first scan driving circuit 11 may be disposed on one side of the display area DA, and the emission control driving circuit 13 may be disposed on the other side thereof.

The pad 14 may be disposed in the second peripheral area PA2 of the substrate 100. The pad 14 may be exposed by not being covered by an insulating layer and may be electrically connected to the display circuit board 30. A pad 34 of the display circuit board 30 may be electrically connected to the pad 14 of the display panel 10.

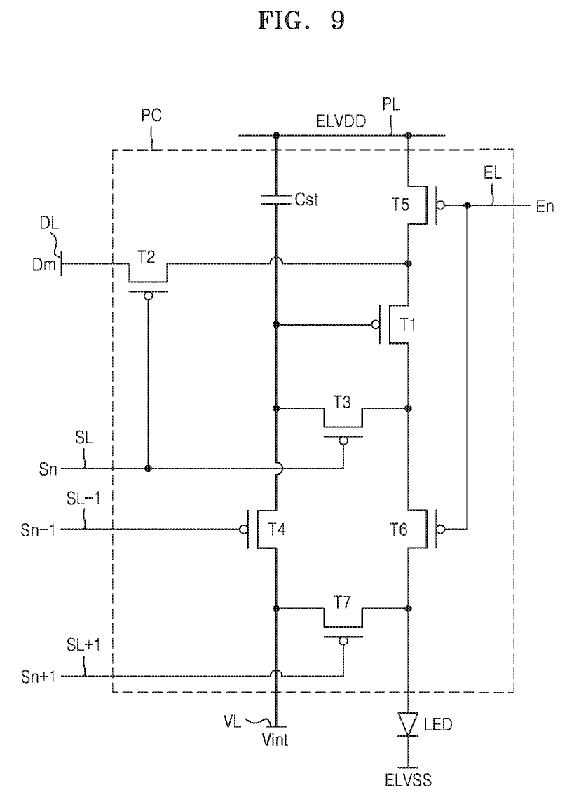

The display circuit board 30 may transmit a signal of a controller or power to the display panel 10. A control signal generated by the controller may be transmitted to each gate driving circuit through the display circuit board 30. Also, the controller may provide a first power voltage ELVDD and a second power voltage ELVSS (see FIG. 9) to the first power supply line 15 and the second power supply line 16. The first power voltage (hereinafter referred to as driving voltage) ELVDD may be provided to each subpixel circuit PC through a driving voltage line PL connected to the first power supply line 15, and the second power voltage (hereinafter referred to as common voltage) ELVSS may be provided to a common electrode of the light emitting diode LED connected to the second power supply line 16. The first power supply line 15 may extend in the first direction (e.g., x-axis direction). The second power supply line 16 may have a loop shape with one side open and thus may partially surround the display area DA.

A data signal of the data driver 20 may be transmitted to the subpixel circuit PC through an input line IL and a data line DL electrically connected to the input line IL.

Thus, the display panel may have a display area and peripheral area, including subpixels made up of light-emitting diode and subpixel circuits, along with integrated gate and emission drivers. The display panel may include flexible regions allowing for bending or folding, and a light control layer composed of metal and light absorption layers that limit viewing angles to enhance privacy and reduce reflections. The system is powered and driven via a circuit board and data drivers, with signals routed through various conductive lines and pads.

FIG. 9 is a circuit diagram schematically illustrating a subpixel circuit of a subpixel disposed in a display area of FIG. 8.

Referring to FIG. 9, the subpixel may include a light emitting diode LED and a subpixel circuit PC. The light emitting diode LED may be electrically connected to the subpixel circuit PC.

The subpixel circuit PC may include a first thin film transistor T1, a second thin film transistor T2, a third thin film transistor T3, a fourth thin film transistor T4, a fifth thin film transistor T5, a sixth thin film transistor T6, a seventh thin film transistor T7, and a storage capacitor Cst.

As a switching thin film transistor, the second thin film transistor T2 may be connected to a scan line SL and a data line DL and may be configured to transmit a data voltage (or a data signal) Dm input from the data line DL to the first thin film transistor T1, based on a scan voltage (or a scan signal) Sn input from the scan line SL. The storage capacitor Cst may be connected to the first thin film transistor T1 and a driving voltage line PL and may be configured to store a voltage corresponding to the difference between a voltage received from the second thin film transistor T2 and a first power voltage ELVDD supplied to the driving voltage line PL.

As a driving thin film transistor, the first thin film transistor T1 may be connected to the driving voltage line PL and the storage capacitor Cst and may be configured to control a driving current flowing from the driving voltage line PL through the light emitting diode LED in response to a voltage value stored in the storage capacitor Cst. The light emitting diode LED may emit light with a certain brightness according to the driving current. A second electrode (e.g., a cathode) of the light emitting diode LED may be supplied with a second power voltage ELVSS.

The third thin film transistor T3 may be a compensation thin film transistor, and the gate electrode of the third thin film transistor T3 may be connected to the scan line SL. The source electrode (or drain electrode) of the third thin film transistor T3 may be connected to the drain electrode (or source electrode) of the first thin film transistor T1 and may be connected to a first electrode of the light emitting diode LED via the sixth thin film transistor T6. The drain electrode (or source electrode) of the third thin film transistor T3 may be connected to any one electrode of the storage capacitor Cst, the source electrode (or drain electrode) of the fourth thin film transistor T4, and the gate electrode of the first thin film transistor T1. The third thin film transistor T3 may be turned on according to a scan signal Sn received through the scan line SL, to connect the gate electrode and the drain electrode of the first thin film transistor T1 to each other to diode-connect the first thin film transistor T1.

The fourth thin film transistor T4 may be an initialization thin film transistor and the gate electrode thereof may be connected to a previous scan line SL-1. The drain electrode (or source electrode) of the fourth thin film transistor T4 may be connected to an initialization voltage line VL. The source electrode (or drain electrode) of the fourth thin film transistor T4 may be connected to any one electrode of the storage capacitor Cst, the drain electrode (or source electrode) of the third thin film transistor T3, and the gate electrode of the first thin film transistor T1. The fourth thin film transistor T4 may be turned on according to a previous scan signal Sn-1 received through the previous scan line SL-1, to transmit an initialization voltage Vint to the gate electrode of the first thin film transistor T1 to perform an initialization operation of initializing the voltage of the gate electrode of the first thin film transistor T1.

The fifth thin film transistor T5 may be an operation control thin film transistor and the gate electrode thereof may be connected to an emission control line EL. The source electrode (or drain electrode) of the fifth thin film transistor T5 may be connected to the driving voltage line PL. The drain electrode (or source electrode) of the fifth thin film transistor T5 may be connected to the source electrode (or drain electrode) of the first thin film transistor T1 and the drain electrode (or source electrode) of the second thin film transistor T2.

The sixth thin film transistor T6 may be an emission control thin film transistor and the gate electrode thereof may be connected to the emission control line EL. The source electrode (or drain electrode) of the sixth thin film transistor T6 may be connected to the drain electrode (or source electrode) of the first thin film transistor T1 and the source electrode (or drain electrode) of the third thin film transistor T3. The drain electrode (or source electrode) of the sixth thin film transistor T6 may be electrically connected to the first electrode of the light emitting diode LED. The fifth thin film transistor T5 and the sixth thin film transistor T6 may be simultaneously turned on according to an emission control signal En received through the emission control line EL, such that the first power voltage ELVDD may be transmitted to the light emitting diode LED and the driving current may flow through the light emitting diode LED.

The seventh thin film transistor T7 may be an initialization thin film transistor that initializes the first electrode of the light emitting diode LED. The gate electrode of the seventh thin film transistor T7 may be connected to a next scan line SL+1. The source electrode (or drain electrode) of the seventh thin film transistor T7 may be connected to the first electrode of the light emitting diode LED. The drain electrode (or source electrode) of the seventh thin film transistor T7 may be connected to the initialization voltage line VL. The seventh thin film transistor T7 may be turned on according to a next scan signal Sn+1 received through the next scan line SL+1, to initialize the first electrode of the light emitting diode LED.

FIG. 9 illustrates a case where the fourth thin film transistor T4 and the seventh thin film transistor T7 are respectively connected to the previous scan line SL-1 and the next scan line SL+1; however, in an embodiment, both the fourth thin film transistor T4 and the seventh thin film transistor T7 may be connected to the previous scan line SL-1 to be driven according to the previous scan signal Sn-1.

Another electrode of the storage capacitor Cst may be connected to the driving voltage line PL. Any one electrode of the storage capacitor Cst may be connected to the gate electrode of the first thin film transistor T1, the drain electrode (or source electrode) of the third thin film transistor T3, and the source electrode (or drain electrode) of the fourth thin film transistor T4.

The second electrode (e.g., cathode) of the light emitting diode LED may be provided with the second power voltage ELVSS. The light emitting diode LED may emit light by receiving a driving current from the first thin film transistor T1.

The light emitting diode LED may be an organic light emitting diode including an organic material as a light emitting material. In an embodiment, the light emitting diode LED may be an inorganic light emitting diode including an inorganic material. The inorganic light emitting diode may include a PN junction diode including inorganic semiconductor-based materials. When a forward voltage is applied to the PN junction diode, holes and electrons may be injected thereinto and energy generated by the recombination of the holes and electrons may be converted into light energy to emit light of a certain color. The inorganic light emitting diode described above may have a width of several to several hundred micrometers or several to several hundred nanometers. In some embodiments, the light emitting diode LED may include a quantum dot light emitting diode. As described above, an emission layer of the light emitting diode LED may include an organic material, may include an inorganic material, may include quantum dots, may include an organic material and quantum dots, or may include an inorganic material and quantum dots. Hereinafter, for convenience of description, a case where the light emitting diode LED includes an organic light emitting diode will be described as an example.

FIG. 9 illustrates that the subpixel circuit PC includes seven thin film transistors and one capacitor; however, in an embodiment, the subpixel circuit PC may include two or more(other than seven) thin film transistors and two or more capacitors. Also, the circuit design of the subpixel circuit PC is not necessarily limited to the illustration in FIG. 9 and may be variously modified.

The first to seventh thin film transistors T1, T2, T3, T4, T5, T6, and T7 may be various types of transistors. In an embodiment, as illustrated in FIG. 9, all of the first to seventh thin film transistors T1, T2, T3, T4, T5, T6, and T7 may be P-channel MOSFET (PMOS). In an embodiment, at least one of the first to seventh thin film transistors T1, T2, T3, T4, T5, T6, and T7 may be P-channel MOSFET (PMOS), and the others may be N-channel MOSFET (NMOS). In an embodiment, all of the first to seventh thin film transistors T1, T2, T3, T4, T5, T6, and T7 may be NMOS. The positions of sources and drains may be interchanged with each other depending on the types (P-type or N-type) of transistors.

All of the first to seventh thin film transistors T1, T2, T3, T4, T5, T6, and T7 illustrated in FIG. 9 may be thin film transistors including a low-temperature polysilicon semiconductor layer. In this case, the first to seventh thin film transistors T1, T2, T3, T4, T5, T6, and T7 are not necessarily limited thereto, and at least one of the first to seventh thin film transistors T1, T2, T3, T4, T5, T6, and T7 may be a thin film transistor including a low-temperature polycrystalline silicon (LTPS) semiconductor layer and the others may be thin film transistors including an oxide semiconductor layer. Alternatively, all of the first to seventh thin film transistors T1, T2, T3, T4, T5, T6, and T7 may be thin film transistors including an oxide semiconductor layer.

FIG. 10 is a cross-sectional view schematically illustrating a portion of the display apparatus of FIG. 6.

Referring to FIG. 10, the display apparatus DV may include a display panel 10 including a substrate 100, a display layer 200, an encapsulation layer 400, a light control layer 500, and a polarization layer 600, an adhesive layer OCA, and a cover window 70.

The substrate 100 may include glass or polymer resin. For example, the polymer resin may include polyether sulfone, polyacrylate, polyether imide, polyethylene naphthalate, polyethylene terephthalate, polyphenylene sulfide, polyarylate, polyimide, polycarbonate, and/or cellulose acetate propionate. The substrate 100 including the polymer resin may be flexible, rollable, or bendable. The substrate 100 may have a multilayer structure including an inorganic layer and a layer including the polymer resin.

The display layer 200 may include a light emitting diode, for example, an organic light emitting diode, a thin film transistor electrically connected thereto, and insulating layers disposed therebetween.

The encapsulation layer 400 may be directly disposed on the display layer 200. The encapsulation layer 400 may include at least one inorganic encapsulation layer and at least one organic encapsulation layer.

In some embodiments, an encapsulation substrate including a glass material may be provided instead of the encapsulation layer 400. The encapsulation substrate may be disposed on the display layer 200, and the display layer 200 may be disposed between the substrate 100 and the encapsulation substrate. There may be a gap between the encapsulation substrate and the display layer 200, and the gap may be filled with a filler.

The light control layer 500 may be disposed on the encapsulation layer 400. The light control layer 500 may reflect or absorb a portion of the light emitted from the display layer 200. Accordingly, the light control layer 500 may reduce the angle of light emitted from the display layer 200.

The polarization layer 600 may be disposed on the light control layer 500. The polarization layer 600 may be an optical functional layer that may reduce the reflectance of light (external light) incident from the outside toward the display panel 10 and/or improve the color purity of light emitted from the display panel 10.

The cover window 70 may be disposed on the polarization layer 600. The cover window 70 may protect the layers being covered. The cover window 70 may be separately formed and then attached to the polarization layer 600 by the adhesive layer OCA disposed between the cover window 70 and the polarization layer 600. The adhesive layer OCA may include, for example, an optically clear adhesive. Alternatively, the cover window 70 may be directly formed over the polarization layer 600.

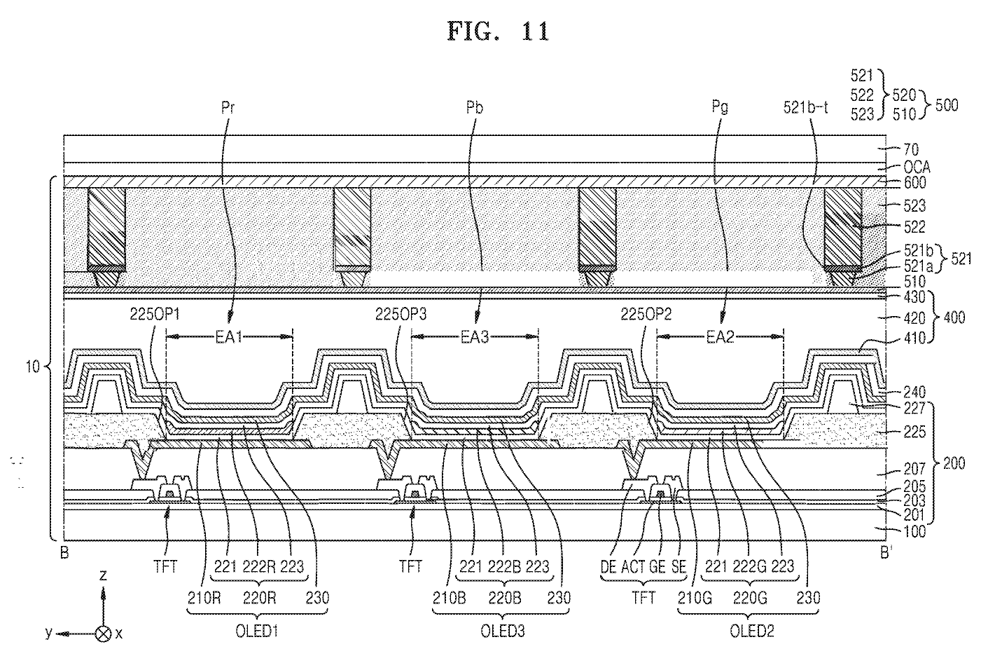

FIG. 11 is a cross-sectional view of the display apparatus taken along line B-B' of FIG. 8.

Referring to FIG. 11, the display apparatus may include a display panel 10 including a substrate 100, a display layer 200, an encapsulation layer 400, a light control layer 500, and a polarization layer 600, an adhesive layer OCA, and a cover window 70.

The display panel 10 may include a plurality of subpixels disposed in the display area DA (see FIG. 8). Each of the plurality of subpixels may emit red, green, or blue light. The plurality of subpixels may include subpixels emitting light of different colors, for example, a first subpixel, a second subpixel, and a third subpixel. The first subpixel may be provided as a plurality of first subpixels, the second subpixel may be provided as a plurality of second subpixels, and the third subpixel may be provided as a plurality of third subpixels. In an embodiment, the first subpixel may be a red subpixel Pr capable of emitting red light, the second subpixel may be a green subpixel Pg capable of emitting green light, and the third subpixel may be a blue subpixel Pb capable of emitting blue light.

The display layer 200 may be disposed on the substrate 100. The display layer 200 may include a subpixel circuit layer and a light emitting diode layer. The subpixel circuit layer may include a thin film transistor TFT and may include a buffer layer 201, a gate insulating layer 203, an interlayer insulating layer 205, and a planarization layer 207 that are each electrically insulating layers.

The buffer layer 201 may be located over the substrate 100 to reduce or block the penetration of foreign materials, moisture, or external air from under the substrate 100 and may provide a flat (e.g., planar) surface over the substrate 100. The buffer layer 201 may include an inorganic material such as oxide or nitride, an organic material, or an organic/inorganic composite and may include a single-layer or multiple-layer structure of an inorganic material and an organic material. A barrier layer for blocking the penetration of external air may be further included between the substrate 100 and the buffer layer 201. For example, the buffer layer 201 may include silicon oxide or silicon nitride.

The thin film transistor TFT may be disposed on the buffer layer 201. The thin film transistor TFT may include a semiconductor layer ACT, a gate electrode GE, a source electrode SE, and a drain electrode DE. The thin film transistor TFT may be connected to an organic light emitting diode to drive the organic light emitting diode.

The semiconductor layer ACT may be disposed on the buffer layer 201. The semiconductor layer ACT may include polysilicon or amorphous silicon. Alternatively, the semiconductor layer ACT may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer ACT may include a channel area, and a source area and a drain area that are doped with dopants.

The gate electrode GE, the source electrode SE, and the drain electrode DE may be formed of various conductive materials. In an embodiment, the gate electrode GE may include at least one of molybdenum (Mo), aluminum (Al), copper (Cu), and titanium (Ti). For example, the gate electrode GE may include a single molybdenum (Mo) layer or may include a three-layer structure including a molybdenum (Mo) layer, an aluminum (Al) layer, and a molybdenum (Mo) layer. In an embodiment, the source electrode SE and the drain electrode DE may include at least one of copper (Cu), titanium (Ti), and aluminum (Al). For example, the source electrode SE and the drain electrode DE may include a three-layer structure including a titanium (Ti) layer, an aluminum (Al) layer, and a titanium (Ti) layer.

Moreover, in order to secure the insulation between the semiconductor layer ACT and the gate electrode GE, the gate insulating layer 203 may be disposed between the semiconductor layer ACT and the gate electrode GE. The interlayer insulating layer 205 may be disposed on the gate electrode GE, and the source electrode SE and the drain electrode DE may be disposed on the interlayer insulating layer 205.

Each of the gate insulating layer 203 and the interlayer insulating layer 205 may include an inorganic material such as silicon oxide, silicon nitride, and/or silicon oxynitride. The gate insulating layer 203 and the interlayer insulating layer 205 may be formed through, for example, chemical vapor deposition (CVD) or atomic layer deposition (ALD).

The planarization layer 207 may be disposed on the thin film transistor TFT. In order to provide a flat upper surface, chemical mechanical polishing may be performed on the upper surface of the planarization layer 207 after the planarization layer 207 is formed. The planarization layer 207 may include a general-purpose polymer such as photosensitive polyimide, polyimide, polystyrene (PS), polycarbonate (PC), benzocyclobutene (BCB), hexamethyldisiloxane (HMDSO), or polymethylmethacrylate (PMMA), a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer. FIG. 11 illustrates that the planarization layer 207 includes a single layer; however, in some embodiments, the planarization layer 207 may include multiple layers. Each of subpixel electrodes 210R, 210G, and 210B of first to third organic light emitting diodes OLED1, OLED2, and OLED3 that are a first display element, a second display element, and a third display element may be electrically connected to the thin film transistor TFT through a contact hole of the planarization layer 207.

The light emitting diode layer may be disposed on the subpixel circuit layer. In an embodiment, the light emitting diode layer may include first to third organic light emitting diodes OLED1, OLED2, and OLED3, a bank layer 225, and a spacer 227.

The first to third organic light emitting diodes OLED1, OLED2, and OLED3 may be disposed on the subpixel circuit layer. The first organic light emitting diode OLED1 may include a first subpixel electrode 210R, a first intermediate layer 220R including a first common layer 221, a first emission layer 222R, and a second common layer 223, and an opposite electrode 230, the second organic light emitting diode OLED2 may include a second subpixel electrode 210G, a second intermediate layer 220G including a first common layer 221, a second emission layer 222G, and a second common layer 223, and an opposite electrode 230, and the third organic light emitting diode OLED3 may include a third subpixel electrode 210B, a third intermediate layer 220B including a first common layer 221, a third emission layer 222B, and a second common layer 223, and an opposite electrode 230.

The first to third subpixel electrodes 210R, 210G, and 210B may be disposed on the planarization layer 207. The first to third subpixel electrodes 210R, 210G, and 210B may be spaced apart from each other.

The first to third subpixel electrodes 210R, 210G, and 210B may be reflective electrodes. The first to third subpixel electrodes 210R, 210G, and 210B may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof, and a transparent or semitransparent conductive layer formed over the reflective layer. The transparent or semitransparent conductive layer may include at least one of indium tin oxide (ITO), indium zinc oxide (IZO), zinc oxide (ZnO), indium oxide (In₂O₃), indium gallium oxide (IGO), and aluminum zinc oxide (AZO).

The bank layer 225 may be disposed on the first to third subpixel electrodes 210R, 210G, and 210B. The bank layer 225 may include first to third opening portions 225OP1, 225OP2, and 225OP3 respectively overlapping the first to third subpixel electrodes 210R, 210G, and 210B and respectively exposing the center portions of the first to third subpixel electrodes 210R, 210G, and 210B. The bank layer 225 may cover the edge of the first to third subpixel electrodes 210R, 210G, and 210B and increase the distance between the edge of the first to third subpixel electrodes 210R, 210G, and 210B and the opposite electrode 230 to prevent an arc or the like from occurring at the edge of the first to third subpixel electrodes 210R, 210G, and 210B.

The first to third opening portions 225OP1, 225OP2, and 225OP3 of the bank layer 225 may define first to third emission areas EA1, EA2, and EA3 of the first to third organic light emitting diodes OLED1, OLED2, and OLED3 included in the respective subpixels. As illustrated in FIG. 11, the bank layer 225 may include the first opening portion 225OP1 defining the first emission area EA1 of the first organic light emitting diode OLED1 of the first subpixel. Also, the bank layer 225 may include the second opening portion 225OP2 defining the second emission area EA2 of the second organic light emitting diode OLED2 of the second subpixel and may include the third opening portion 225OP3 defining the third emission area EA3 of the third organic light emitting diode OLED3 of the third subpixel.

The bank layer 225 may include an organic insulating material. Alternatively, the bank layer 225 may include an inorganic insulating material such as silicon nitride or silicon oxide. In some embodiments, the bank layer 225 may include an organic insulating material and an inorganic insulating material.

In an embodiment, the bank layer 225 may include a light-blocking material. For example, the light-blocking material of the bank layer 225 may be black. The light-blocking material may include a resin or paste including carbon black, carbon nanotube, or black dye, metal particles (e.g., nickel, aluminum, molybdenum, or any alloy thereof), metal oxide particles, or metal nitride particles. When the bank layer 225 includes a light-blocking material, the reflection of external light by metal structures disposed under the bank layer 225 may be reduced.

The spacer 227 may be disposed on the bank layer 225. The spacer 227 may include an organic insulating material such as polyimide. Alternatively, the spacer 227 may include an inorganic insulating material such as silicon nitride or silicon oxide or may include an organic insulating material and an inorganic insulating material. In an embodiment, the spacer 227 may include a different material than the bank layer 225 including the above light-blocking material and may be formed in a separate process from the bank layer 225.

In an embodiment, the spacer 227 may include the same material as the bank layer 225. In this case, the bank layer 225 and the spacer 227 may be formed together in a mask process using a halftone mask.

An intermediate layer may be disposed on the first to third subpixel electrodes 210R, 210G, and 210B and the bank layer 225. As described above, the intermediate layer may include a first common layer 221, emission layers 222R, 222G, and 222B, and a second common layer 223.

The first to third emission layers 222R, 222G, and 222B may be disposed in the first to third opening portions 225OP1, 225OP2, and 225OP3 of the bank layer 225. The first to third emission layers 222R, 222G, and 222B may include an organic material including a fluorescent or phosphorescent material capable of emitting red, green, or blue light. The above organic material may include a low-molecular weight organic material (e.g., having a molecular weight of 800 g/mol or less) or a high-molecular weight organic material (e.g., having a molecular weight of 3,000 g/mol or more).

The first common layer 221 and the second common layer 223 may be respectively disposed under and over the emission layer. The first common layer 221 may include, for example, a hole transport layer (HTL) or may include an HTL and a hole injection layer (HIL). The second common layer 223 may include, for example, an electron transport layer (ETL) or may include an ETL and an electron injection layer (EIL). In an embodiment, the second common layer 223 may be omitted.

The emission layer may be disposed in each subpixel to correspond to the first to third opening portions 225OP1, 225OP2, and 225OP3 of the bank layer 225, whereas each of the first common layer 221 and the second common layer 223 may be integrally formed to entirely cover the substrate 100. For example, each of the first common layer 221 and the second common layer 223 may be integrally formed to entirely cover the display area DA of the substrate 100.

The opposite electrode 230 may be a cathode that is an electron injection electrode. The opposite electrode 230 may include a conductive material having a low work function (e.g., 4.0 eV or less). For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 230 may further include a layer such as ITO, IZO, ZnO, or In₂O₃ over the (semi)transparent layer including the above material.

In an embodiment, a capping layer 240 may be further disposed on the display layer 200. The capping layer 240 may be disposed on the first to third organic light emitting diodes OLED1, OLED2, and OLED3. In an embodiment, the capping layer 240 may improve the light emission efficiency of the first to third organic light emitting diodes OLED1, OLED2, and OLED3 by the principle of constructive interference.

The capping layer 240 may be an organic capping layer including an organic material, an inorganic capping layer including an inorganic material, or a composite capping layer including an organic material and an inorganic material. For example, the capping layer 240 may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be selectively substituted with a substituent including O, N, S, Se, Si, F, Cl, Br, I, or any combination thereof.

The encapsulation layer 400 may be disposed on the capping layer 240. The encapsulation layer 400 may include at least one inorganic encapsulation layer and at least one organic encapsulation layer. For example, as illustrated in FIG. 11, the encapsulation layer 400 may include a first inorganic encapsulation layer 410, an organic encapsulation layer 420, and a second inorganic encapsulation layer 430 that are sequentially stacked.

The first inorganic encapsulation layer 410 and the second inorganic encapsulation layer 430 may include an inorganic insulating material such as silicon oxide, silicon nitride, silicon oxynitride, aluminum oxide, titanium oxide, tantalum oxide, hafnium oxide, or zinc oxide. The first inorganic encapsulation layer 410 and the second inorganic encapsulation layer 430 may have a single-layer or multiple-layer structure including the above inorganic insulating material.

The organic encapsulation layer 420 may relieve the internal stress of the first inorganic encapsulation layer 410 and/or the second inorganic encapsulation layer 430. The organic encapsulation layer 420 may include a polymer-based material. For example, the organic encapsulation layer 420 may include polyethyleneterephthalate, polyethylenenaphthalate, polycarbonate, polyimide, polyethylenesulfonate, polyoxymethylene, polyarylate, hexamethyldisiloxane, acryl-based resin (e.g., polymethylmethacrylate or polyacrylic acid), or any combination thereof.

The encapsulation layer 400 may have a multilayer structure of the first inorganic encapsulation layer 410, the organic encapsulation layer 420, and the second inorganic encapsulation layer 430. In this case, even when a crack occurs in the encapsulation layer 400, the crack might not propagate between the first inorganic encapsulation layer 410 and the organic encapsulation layer 420 or between the organic encapsulation layer 420 and the second inorganic encapsulation layer 430. The encapsulation layer 400 may prevent or minimize the penetration of external moisture or oxygen into the display area DA.

The light control layer 500 may be disposed on the encapsulation layer 400. The light control layer 500 may include a light control planarization layer 510 and a light path layer 520.

The light path layer 520 may include a metal layer 521, a light absorption layer 522, and a light transmission layer 523.

The light control planarization layer 510 may include an organic material such as an epoxy-based resin, an acrylic resin, or an imide-based resin. In some embodiments, the light control planarization layer 510 may include an ethylene glycol di(meth)acrylate-based polymer, a diethylene glycol di(meth)acrylate-based polymer, a triethylene glycol di(meth)acrylate-based polymer, a 1,6-hexanediol di(meth)acrylate-based polymer, a pentaerythritol tri(meth)acrylate-based polymer, a pentaerythritol tetra(meth)acrylate-based polymer, a dipentaerythritol penta(meth)acrylate-based polymer, a dipentaerythritol hexa(meth)acrylate-based polymer, a bisphenol A epoxy(meth)acrylate-based polymer, an ethylene glycol monomethyl ether (meth)acrylate-based polymer, a trimethylolpropane tri(meth)acrylate-based polymer, a trisacryloyloxyethyl phosphate-based polymer, or a carboxylic acid epoxy diacrylate-based polymer. In an embodiment, the light control planarization layer 510 may include a propylene glycol methyl ether acetate, a methacrylic acid-benzylmethacrylic acid copolymer, a multi-functional acrylate, and a photo initiator.

In this case, the light control planarization layer 510 may be disposed on the encapsulation layer 400 by using an inkjet method. The light control planarization layer 510 may planarize the curvature of the encapsulation layer 400.

The metal layer 521 may be disposed on the light control planarization layer 510. The metal layer 521 may include a first metal layer 521a and a second metal layer 521b that are sequentially disposed on the light control planarization layer 510. The first metal layer 521a may include aluminum, and the second metal layer 521b may include titanium. The side surface of the first metal layer 521a may be inclined. For example, the side surface of the first metal layer 521a may have a reverse tapered shape. The width of the first metal layer 521a may be different in the thickness direction of the first metal layer 521a. For example, the width of the first metal layer 521a may increase from a portion of the first metal layer 521a at which the first metal layer 521a and the light control planarization layer 510 contact each other to a portion of the first metal layer 521a at which the first metal layer 521a and the second metal layer 521b contact each other. The second metal layer 521b may include a first tip portion 521b-t protruding from the side surface of the first metal layer 521a. The first tip portion 521b-t may protrude in a direction away from the first metal layer 521a from the end of a surface at which the first metal layer 521a and the second metal layer 521b contact each other. In the above case, the first metal layer 521a and the second metal layer 521b may change the path of light or block light by reflecting light emitted from at least one of the first to third organic light emitting diodes OLED1, OLED2, and OLED3 under the metal layer 521. The metal layer 521 may partially block the path of light reflected by the side surface of the first metal layer 521a, by including the first tip portion 521b-t. Also, the first tip portion 521b-t may increase the bonding area between the metal layer 521 and the light transmission layer 523, thus increasing the bonding force with respect to the light transmission layer 523 around the metal layer 521.

A portion of the metal layer 521 that is not the first tip portion 521b-t may be considered a remainder of the metal layer 521 or a base portion thereof. This base portion of the metal layer 521 may have a substantially flared cone shape.

The light absorption layer 522 may be disposed on the metal layer 521. The light absorption layer 522 may contact the upper surface of the metal layer 521. The light absorption layer 522 may include an organic insulating material and/or an inorganic insulating material such as silicon nitride or silicon oxide. The light absorption layer 522 may include a light-blocking material. For example, the light-blocking material of the light absorption layer 522 may be black. The light-blocking material may include a resin or paste including carbon black, carbon nanotube, or black dye, metal particles (e.g., nickel, aluminum, molybdenum, or any alloy thereof), metal oxide particles, or metal nitride particles. The thickness of the light absorption layer 522 may be less than or equal to the thickness of the light transmission layer 523.

The metal layer 521 and the light absorption layer 522 described above may be respectively provided as a plurality of metal layers 521 and a plurality of light absorption layers 522. The plurality of metal layers 521 may be spaced apart from each other, and each light absorption layer 522 may be disposed on each metal layer 521. For example, the plurality of metal layers 521 and the plurality of light absorption layers 522 may be alternately stacked. The metal layer 521 and the light absorption layer 522 may also overlap at least one of the first to third emission areas EA1, EA2, and EA3.

The light transmission layer 523 may be disposed between adjacent metal layers 521 and between adjacent light absorption layers 522. The light transmission layer 523 may surround the metal layer 521 and the light absorption layer 522. Also, the light transmission layer 523 may be disposed under the metal layer 521. For example, the light transmission layer 523 may contact the side surface of the first metal layer 521a and the lower surface of the second metal layer 521b. The light transmission layer 523 may include an organic material that may be formed by ink jet, and may include an acrylic resin (e.g., polymethyl methacrylate or polyacrylic acid), ethylhexyl acrylate, pentafluoropropyl acrylate, polyethylene glycol dimethacrylate, or ethylene glycol dimethacrylate. The light transmission layer 523 may include a multi-functional acrylate and a photo initiator.

The light transmission layer 523 may be transparent to allow light emitted from the first to third organic light emitting diodes OLED1, OLED2, and OLED3 to pass therethrough.

The polarization layer 600 may be disposed on the light control layer 500. The polarization layer 600 may be a polarization film including a phase retarder and/or a polarizer. The phase retarder may include a λ/2 (e.g., half-wave plate) phase retarder and/or a λ/4 (e.g., quarter-wave plate) phase retarder.

The adhesive layer OCA may be disposed on the polarization layer 600, and the cover window 70 may be disposed on the adhesive layer OCA.

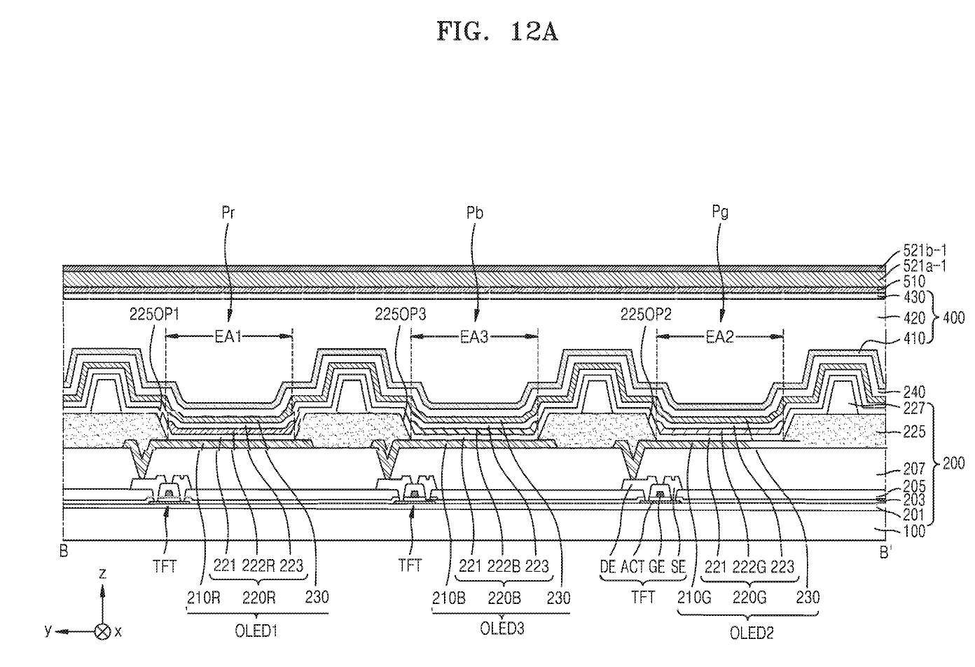

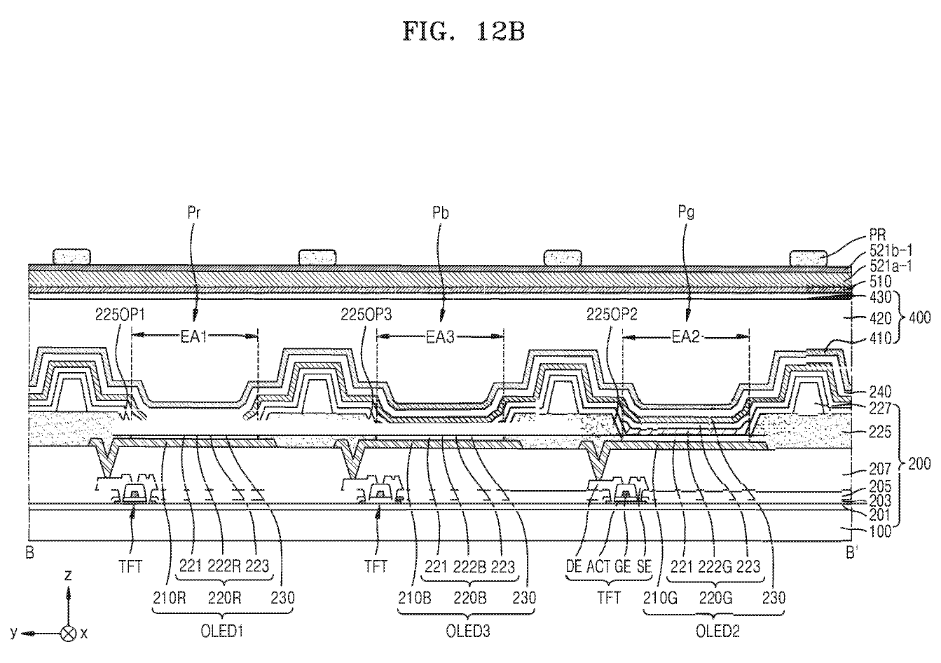

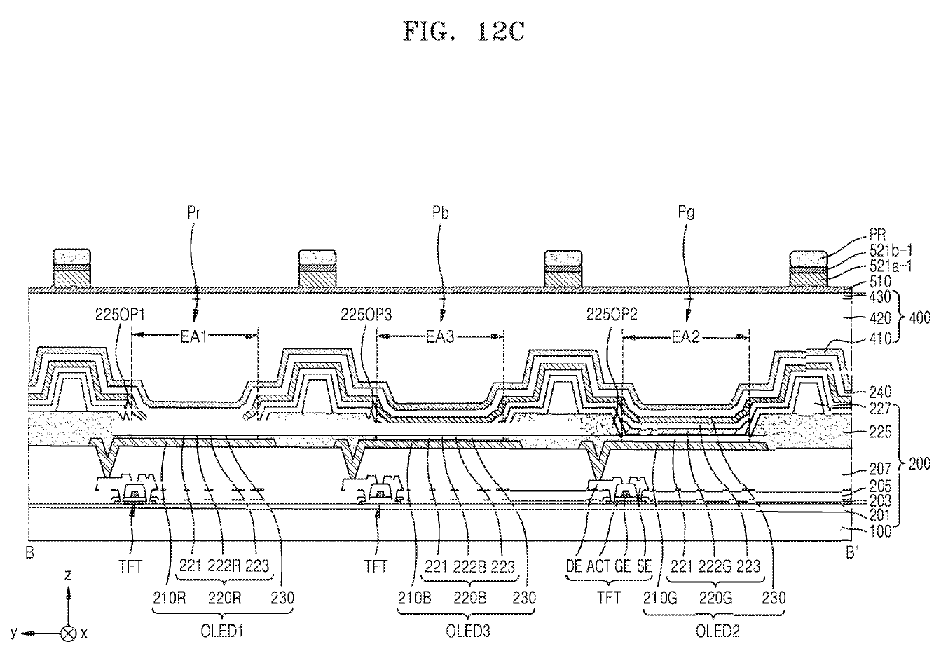

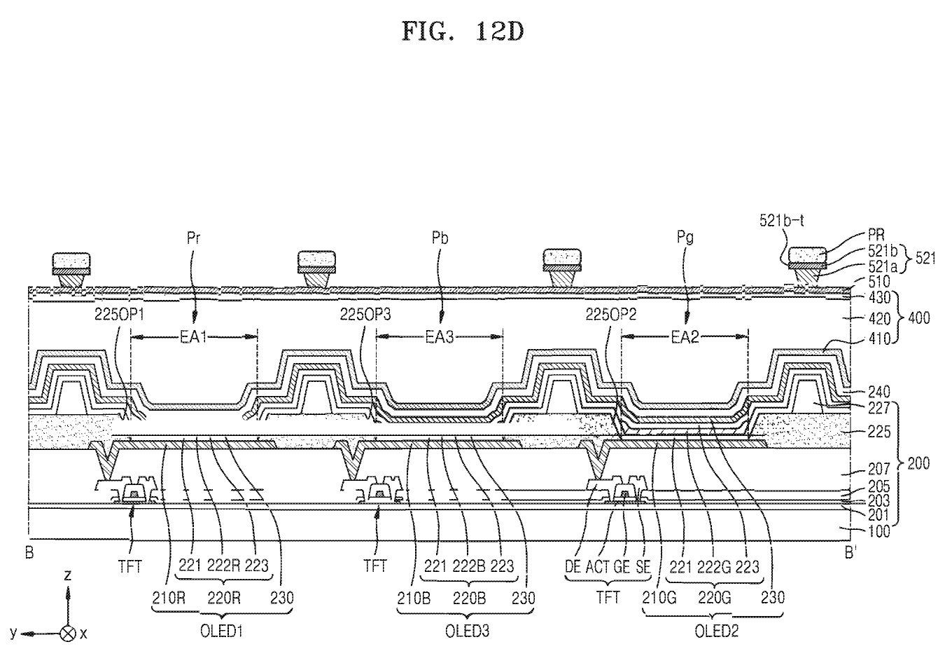

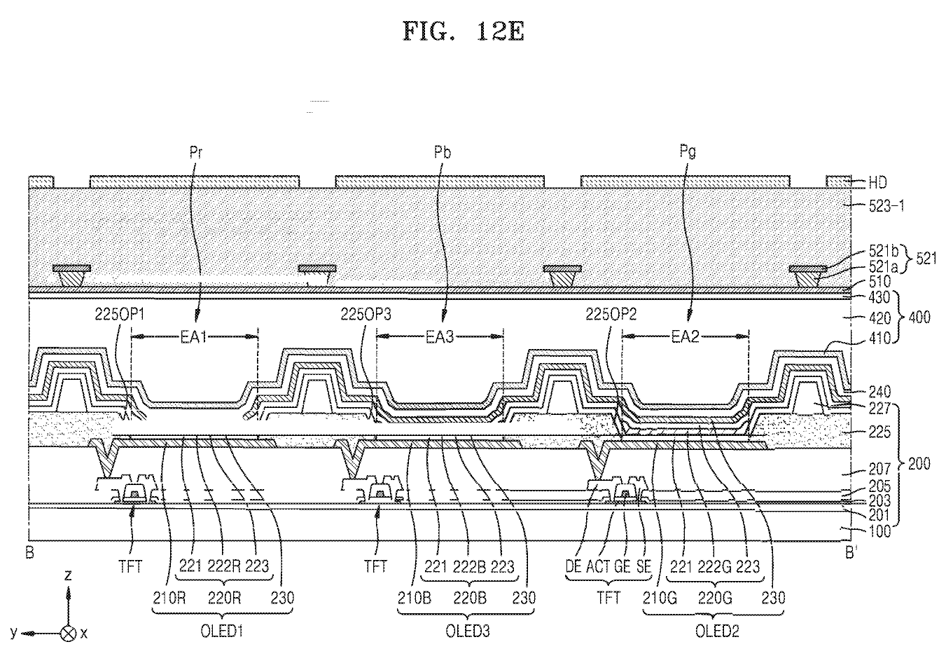

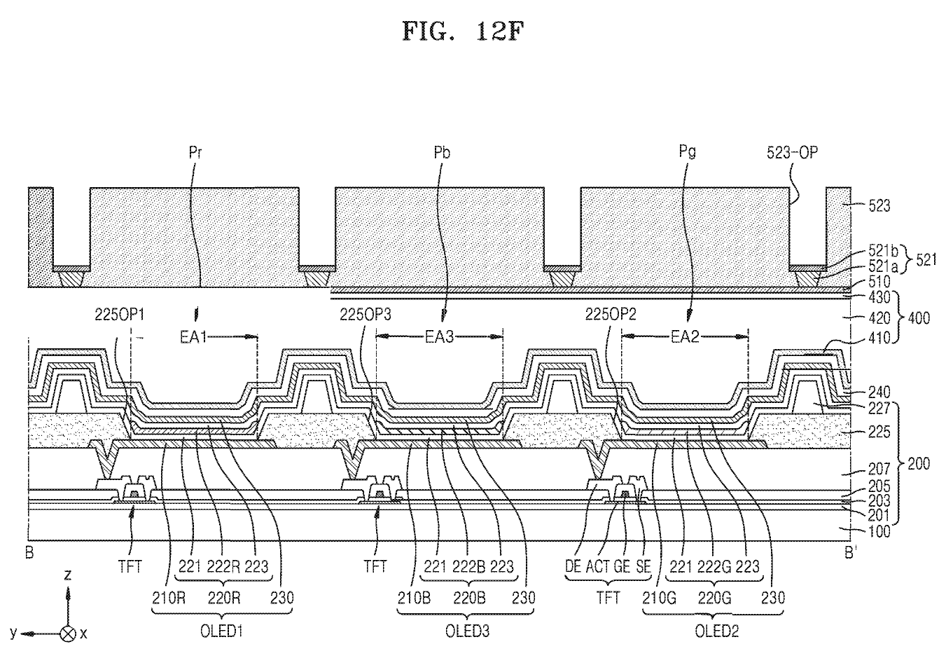

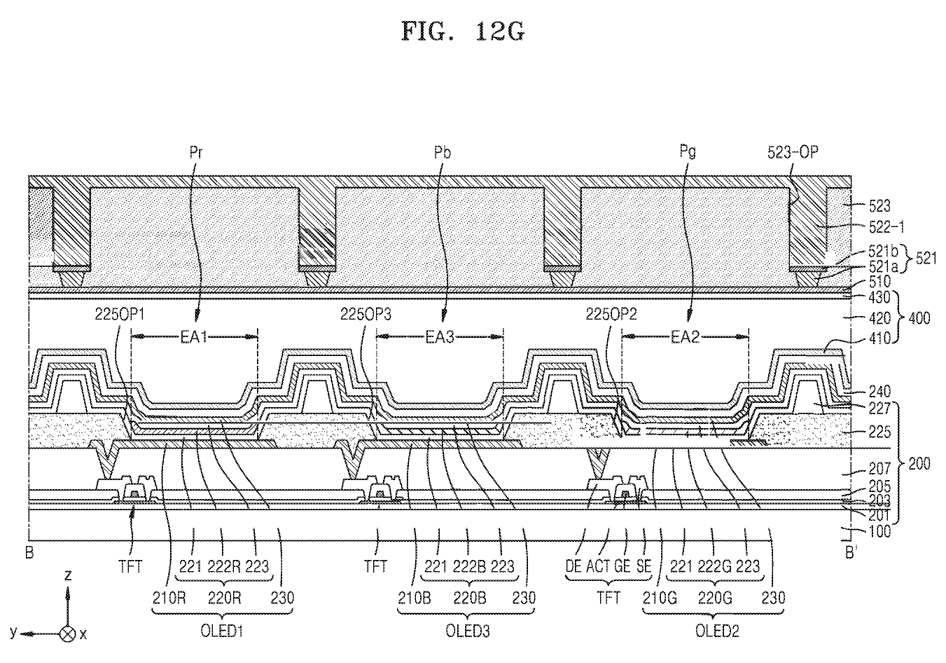

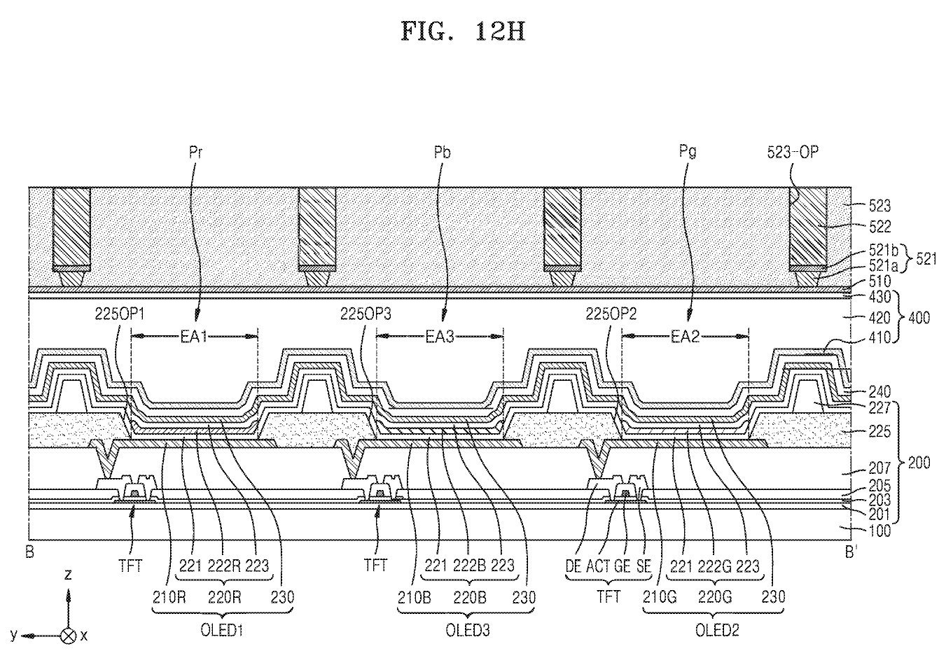

FIGS. 12A to 12H are cross-sectional views schematically illustrating a manufacturing order of the display panel of FIG. 11. In FIGS. 12A to 12H, the same reference numerals as those in FIG. 11 may denote the same members.

Referring to FIG. 12A, a light control planarization layer 510 may be disposed on an encapsulation layer 400. Also, a first metal parent material layer 521a-1 and a second metal parent material layer 521b-1 may be disposed on the light control planarization layer 510. In this case, the first metal parent material layer 521a-1 and the second metal parent material layer 521b-1 may entirely cover the display area DA illustrated in FIG. 8.

Referring to FIG. 12B, a photoresist PR may be disposed on the second metal parent material layer 521b-1. Thereafter, a pattern of the photoresist PR may be formed. In this case, the photoresist PR may be at a position where the first metal layer 521a and the second metal layer 521b illustrated in FIG. 11 are disposed. Also, the photoresist PR may be disposed in a stripe shape in the display area DA similarly to the light absorption layer 522 illustrated in FIG. 7A.

Referring to FIG. 12C, the first metal parent material layer 521a-1 and the second metal parent material layer 521b-1 over which the photoresist PR is not disposed may be removed by dry etching. In this case, the first metal parent material layer 521a-1 and the second metal parent material layer 521b-1 may include an opening disposed between photoresists PR.

Referring to FIG. 12D, wet etching may be performed in a state where the photoresist PR is disposed. In this case, the first metal parent material layer 521a-1 may be a first metal layer 521a having an inclined surface, and the second metal parent material layer 521b-1 may be a second metal layer 521b including a first tip portion 521b-t. When the wet etching is completed, the photoresist PR may be removed.

Referring to FIG. 12E, a light transmission parent material layer 523-1 may be disposed on the first metal layer 521a and the second metal layer 521b. The light transmission parent material layer 523-1 may be in the form of a resin and may be supplied by using an inkjet method.

A hard mask HD may be disposed on the light transmission parent material layer 523-1. In this case, the hard mask HD may include a metal such as aluminum. Also, the hard mask HD may include an opening in a portion corresponding to the first metal layer 521a and the second metal layer 521b.

Referring to FIG. 12F, the light transmission parent material layer 523-1 exposed through the opening of the hard mask HD may be removed by dry etching. A light transmission layer 523 including an opening area 523-OP may be formed by removing a portion of the light transmission parent material layer 523-1 by dry etching. When the above process is completed, the hard mask HD may be removed.

Referring to FIG. 12G, a light absorption parent material layer 522-1 may be supplied to the light transmission layer 523 and the opening area 523-OP through a nozzle by using an inkjet method. In this case, the light absorption parent material layer 522-1 may be disposed not only in the opening area 523-OP but also on the upper surface of the light transmission layer 523.

Referring to FIG. 12H, a light absorption layer 522 may be formed by removing the light absorption parent material layer 522-1 disposed on the upper surface of the light transmission layer 523 such that the light absorption parent material layer 522-1 is disposed only in the opening area 523-OP.

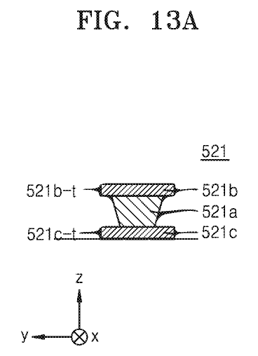

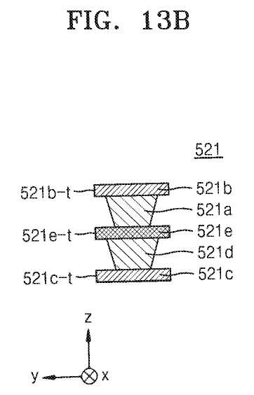

FIG. 13A is a cross-sectional view schematically illustrating a metal layer of a display panel according to an embodiment.

Referring to FIG. 13A, a display apparatus may include a display panel including a substrate, a display layer, an encapsulation layer, a light control layer, and a polarization layer, an adhesive layer, and a cover window. In this case, the substrate, the display layer, the encapsulation layer, the polarization layer, the adhesive layer, and the cover window may be the same as or similar to those described above with reference to FIG. 11, and thus, to the extent that an element is not described in detail with respect to this figure, it may be understood that the element is at least similar to a corresponding element that has been described elsewhere within the present disclosure.

The light control layer may include a light control planarization layer, a metal layer 521, a light absorption layer, and a light transmission layer. In this case, the light control planarization layer, the light absorption layer, and the light transmission layer may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 may include a first metal layer 521a, a second metal layer 521b, and a third metal layer 521c. In this case, the first metal layer 521a and the second metal layer 521b may be the same as or similar to those described above with reference to FIG. 11, and thus, to the extent that an element is not described in detail with respect to this figure, it may be understood that the element is at least similar to a corresponding element that has been described elsewhere within the present disclosure.

The third metal layer 521c may be disposed between the first metal layer 521a and the light control planarization layer. The third metal layer 521c may be formed the same as or similarly to the second metal layer 521b. Also, the third metal layer 521c may include a second tip portion 521c-t similar to a first tip portion 521b-t of the second metal layer 521b. The third metal layer 521c may include the same material as the second metal layer 521b.

The third metal layer 521c may be disposed on the light control planarization layer to safely support the first metal layer 521a. Also, the third metal layer 521c may increase the bonding force with respect to the first metal layer 521a.

The first to third metal layers 521a to 521c described above may be disposed on the light control planarization layer in a similar manner to that described above with reference to FIGS. 12A to 12D. For example, by sequentially stacking a third metal parent material layer, a first metal parent material layer, and a second metal parent material layer over the light control planarization layer and then forming a photoresist pattern and performing dry etching and wet etching thereon, the third metal layer 521c, the first metal layer 521a, and the second metal layer 521b may be disposed on the light control planarization layer.

Thereafter, the light transmission layer and the light absorption layer may be disposed on the light control planarization layer and the metal layer 521 through the process illustrated in FIGS. 12E to 12H.

FIG. 13B is a cross-sectional view schematically illustrating a metal layer of a display panel according to an embodiment.

Referring to FIG. 13B, a display apparatus may include a display panel including a substrate, a display layer, an encapsulation layer, a light control layer, and a polarization layer, an adhesive layer, and a cover window. In this case, the substrate, the display layer, the encapsulation layer, the polarization layer, the adhesive layer, and the cover window may be the same as or similar to those described above with reference to FIG. 11, and thus, to the extent that an element is not described in detail with respect to this figure, it may be understood that the element is at least similar to a corresponding element that has been described elsewhere within the present disclosure.

The light control layer may include a light control planarization layer, a metal layer 521, a light absorption layer, and a light transmission layer. In this case, the light control planarization layer, the light absorption layer, and the light transmission layer may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 may include a first metal layer 521a, a second metal layer 521b, a third metal layer 521c, a fourth metal layer 521d, and a fifth metal layer 521e. In this case, the first to third metal layers 521a to 521c may be the same as or similar to those described above with reference to FIG. 13A, and thus, to the extent that an element is not described in detail with respect to this figure, it may be understood that the element is at least similar to a corresponding element that has been described elsewhere within the present disclosure.

The fourth metal layer 521d may be disposed between the third metal layer 521c and the fifth metal layer 521e. The fourth metal layer 521d may be formed the same as or similarly to the first metal layer 521a. For example, a side surface of the fourth metal layer 521d may be inclined. Also, the fourth metal layer 521d may include the same material as the first metal layer 521a. The fifth metal layer 521e may be disposed between the first metal layer 521a and the fourth metal layer 521d. The fifth metal layer 521e may include a third tip portion 521e-t similar to a first tip portion 521b-t of the second metal layer 521b and/or a second tip portion 521c-t of the third metal layer 521c. The fifth metal layer 521e may include a different material than the first metal layer 521a, the second metal layer 521b, the third metal layer 521c, and the fourth metal layer 521d. For example, the fifth metal layer 521e may include tantalum (Ta).

The fifth metal layer 521e may be disposed on the fourth metal layer 521d to safely support the first metal layer 521a. Also, the first tip portion 521b-t, the second tip portion 521c-t, and the third tip portion 521e-t may increase the bonding force with respect to the light transmission layer.

The first to fifth metal layers 521a to 521e described above may be disposed on the light control planarization layer in a similar manner to that described above with reference to FIGS. 12A to 12D. For example, by sequentially stacking a third metal parent material layer, a fourth metal parent material layer, a fifth metal parent material layer, a first metal parent material layer, and a second metal parent material layer over the light control planarization layer and then forming a photoresist pattern and performing dry etching and wet etching thereon, the third metal layer 521c, the fourth metal layer 521d, the fifth metal layer 521e, the first metal layer 521a, and the second metal layer 521b may be disposed on the light control planarization layer.

Thereafter, the light transmission layer and the light absorption layer may be disposed on the light control planarization layer and the metal layer 521 through the process illustrated in FIGS. 12E to 12H.

In relation to the structure illustrated in FIG. 13B, the metal layer 521 might not include the third metal layer 521c.

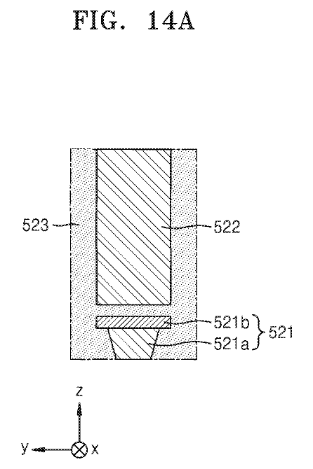

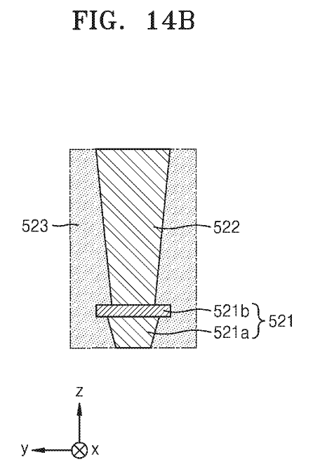

FIG. 14A is a cross-sectional view schematically illustrating a metal layer and a light absorption layer of a display panel according to an embodiment.

Referring to FIG. 14A, a display apparatus may include a display panel including a substrate, a display layer, an encapsulation layer, a light control layer, and a polarization layer, an adhesive layer, and a cover window. In this case, the substrate, the display layer, the encapsulation layer, the polarization layer, the adhesive layer, and the cover window may be the same as or similar to those described above with reference to FIG. 11, and thus, to the extent that an element is not described in detail with respect to this figure, it may be understood that the element is at least similar to a corresponding element that has been described elsewhere within the present disclosure.

The light control layer may include a light control planarization layer, a metal layer 521, a light absorption layer 522, and a light transmission layer 523. In this case, the light control planarization layer, the metal layer 521, and the light transmission layer 523 may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 may include a first metal layer 521a and a second metal layer 521b. The first metal layer 521a and the second metal layer 521b may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 and the light absorption layer 522 may be spaced apart from each other to a certain extent. For example, the metal layer 521 and the light absorption layer 522 may be spaced apart from each other in a height direction of the light absorption layer 522. For example, one surface of the metal layer 521 might not contact the light absorption layer 522. In this case, the light transmission layer 523 may be inserted between the metal layer 521 and the light absorption layer 522. Also, the metal layer 521 may contact the light control planarization layer.

In the above case, because the metal layer 521 is present, even when the light absorption layer 522 is spaced from the metal layer 521 or the light control planarization layer, the spread of light emitted from the display layer may be reduced to some extent by the metal layer 521.

The metal layer 521 may also have the shape described above with reference to FIGS. 13A and 13B.

FIG. 14B is a cross-sectional view schematically illustrating a metal layer and a light absorption layer of a display panel according to an embodiment.

Referring to FIG. 14B, a display apparatus may include a display panel including a substrate, a display layer, an encapsulation layer, a light control layer, and a polarization layer, an adhesive layer, and a cover window. In this case, the substrate, the display layer, the encapsulation layer, the polarization layer, the adhesive layer, and the cover window may be the same as or similar to those described above with reference to FIG. 11, and thus, to the extent that an element is not described in detail with respect to this figure, it may be understood that the element is at least similar to a corresponding element that has been described elsewhere within the present disclosure.

The light control layer may include a light control planarization layer, a metal layer 521, a light absorption layer 522, and a light transmission layer 523. In this case, the light control planarization layer, the metal layer 521, and the light transmission layer 523 may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 may include a first metal layer 521a and a second metal layer 521b. The first metal layer 521a and the second metal layer 521b may be the same as or similar to those described above with reference to FIG. 11, and thus, to the extent that an element is not described in detail with respect to this figure, it may be understood that the element is at least similar to a corresponding element that has been described elsewhere within the present disclosure.

The side surface of the cross-section of the light absorption layer 522 perpendicular to the lengthwise direction thereof may be inclined. For example, the side surface of the light absorption layer 522 may have an inclined surface. In this case, the width of the light absorption layer 522 may increase away from the metal layer 521. Accordingly, the angle at which light spreads may be reduced by narrowing the path through which light passes. For example, in this case, the viewing angle at which an image implemented on the display panel may be recognized may be narrowed.

The metal layer 521 may also have the shape described above with reference to FIGS. 13A and 13B.

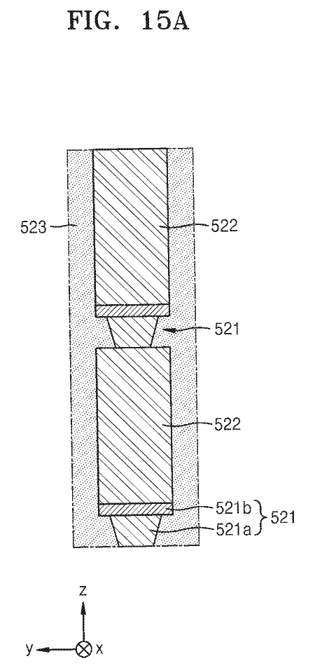

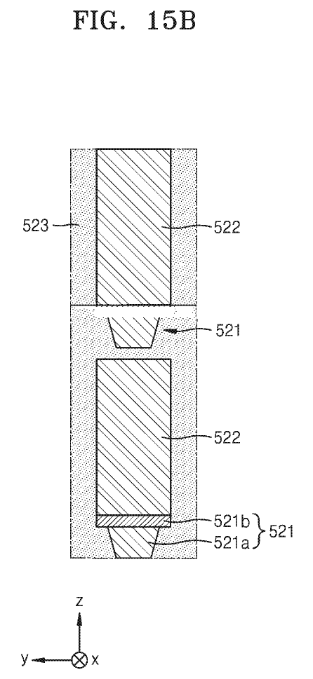

FIG. 15A is a cross-sectional view schematically illustrating a metal layer and a light absorption layer of a display panel according to an embodiment.

Referring to FIG. 15A, a display apparatus may include a display panel including a substrate, a display layer, an encapsulation layer, a light control layer, and a polarization layer, an adhesive layer, and a cover window. In this case, the substrate, the display layer, the encapsulation layer, the polarization layer, the adhesive layer, and the cover window may be the same as or similar to those described above with reference to FIG. 11, and thus, to the extent that an element is not described in detail with respect to this figure, it may be understood that the element is at least similar to a corresponding element that has been described elsewhere within the present disclosure.

The light control layer may include a light control planarization layer, a metal layer 521, a light absorption layer 522, and a light transmission layer 523. In this case, the light control planarization layer, the metal layer 521, and the light transmission layer 523 may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 may include a first metal layer 521a and a second metal layer 521b. The first metal layer 521a and the second metal layer 521b may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layers 521 and the light absorption layer 522 may be respectively provided as a plurality of metal layers 521 and a plurality of light absorption layers 522, and one metal layer 521 and one light absorption layer 522 may form one group. A plurality of groups may also be stacked in the thickness direction of the light transmission layer 523. In this case, the metal layer 521 and the light absorption layer 522 adjacent to each other may contact each other. For example, the metal layer 521 may be disposed on the upper surface of the light absorption layer 522 disposed thereunder. Through this structure, by arranging the metal layer 521 on the light absorption layers 522, some light emitted from the display layer and reflected or refracted in the light control layer may be reflected in the downward direction of the light control layer through the metal layer 521.

In order to form the above structure, the process illustrated in FIGS. 12A to 12G may be performed a plurality of times.

The metal layer 521 may also have the shape described above with reference to FIGS. 13A and 13B.

At least three groups formed by the metal layer 521 and the light absorption layer 522 may be stacked.

FIG. 15B is a cross-sectional view schematically illustrating a metal layer and a light absorption layer of a display panel according to an embodiment.

Referring to FIG. 15B, a display apparatus may include a display panel including a substrate, a display layer, an encapsulation layer, a light control layer, and a polarization layer, an adhesive layer, and a cover window. In this case, the substrate, the display layer, the encapsulation layer, the polarization layer, the adhesive layer, and the cover window may be the same as or similar to those described above with reference to FIG. 11, and thus, to the extent that an element is not described in detail with respect to this figure, it may be understood that the element is at least similar to a corresponding element that has been described elsewhere within the present disclosure.

The light control layer may include a light control planarization layer, a metal layer 521, a light absorption layer 522, and a light transmission layer 523. In this case, the light control planarization layer, the metal layer 521, and the light transmission layer 523 may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layer 521 may include a first metal layer 521a and a second metal layer 521b. The first metal layer 521a and the second metal layer 521b may be the same as or similar to those described above with reference to FIG. 11, and thus, to the extent that an element is not described in detail with respect to this figure, it may be understood that the element is at least similar to a corresponding element that has been described elsewhere within the present disclosure.

The metal layers 521 and the light absorption layer 522 may be respectively provided as a plurality of metal layers 521 and a plurality of light absorption layers 522, and one metal layer 521 and one light absorption layer 522 may form one group. A plurality of groups may also be stacked in the thickness direction of the light transmission layer 523. In this case, adjacent groups may be spaced apart from each other. For example, the light absorption layer 522 disposed on the lower side and the metal layer 521 disposed on the upper side in FIG. 15B may be spaced apart from each other, and the light transmission layer 523 may be disposed in the space therebetween.

In order to form the above structure, the process illustrated in FIGS. 12A to 12G may be performed a plurality of times.

The metal layer 521 may also have the shape described above with reference to FIGS. 13A and 13B.

At least three groups formed by the metal layer 521 and the light absorption layer 522 may be stacked. The metal layer 521 and the light absorption layer 522 of each group may be spaced apart from each other as illustrated in FIG. 14A.

The display panel and the electronic devices according to embodiments may provide a certain range of viewing angles.

It should be understood that embodiments described herein should be considered in a descriptive sense only and not necessarily for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display panel, comprising:
a substrate;
a display layer disposed on the substrate;
an encapsulation layer disposed on the display layer;
a metal layer disposed on the encapsulation layer and including a tip portion that protrudes in one direction; and
a light absorption layer disposed on the metal layer.

2. The display panel of claim 1, wherein the metal layer comprises:
a first metal layer disposed on the encapsulation layer; and
a second metal layer disposed on the first metal layer and including the tip portion that protrudes further than a side surface of the first metal layer in a direction away from the side surface of the first metal layer.

3. The display panel of claim 2, wherein the side surface of the first metal layer is inclined.

4. The display panel of claim 2, wherein the metal layer further comprises a third metal layer disposed between the encapsulation layer and the first metal layer.

5. The display panel of claim 4, wherein the second metal layer and the third metal layer include a same material.

6. The display panel of claim 4, wherein the third metal layer includes a second tip portion that protrudes further than the side surface of the first metal layer in the direction away from the side surface of the first metal layer.

7. The display panel of claim 4, wherein the metal layer further comprises:
a fourth metal layer disposed on the third metal layer; and
a fifth metal layer disposed between the first metal layer and the fourth metal layer.

8. The display panel of claim 7, wherein the fifth metal layer comprises a different material than that of the second metal layer.

9. The display panel of claim 7, wherein the fifth metal layer includes a third tip portion that protrudes further than the side surface of the first metal layer in the direction away from the side surface of the first metal layer.

10. The display panel of claim 7, wherein a side surface of the fourth metal layer is inclined.

11. The display panel of claim 1, further comprising a light transmission layer surrounding the metal layer and the light absorption layer.

12. The display panel of claim 1, further comprising a light control planarization layer disposed between the metal layer and the encapsulation layer.

13. The display panel of claim 1, wherein the metal layer and the light absorption layer are in a line shape in a plan view.

14. The display panel of claim 1, wherein the metal layer and the light absorption layer are respectively provided as a plurality of metal layers and a plurality of light absorption layers, and
wherein the plurality of metal layers and the plurality of light absorption layers are alternately stacked.

15. The display panel of claim 1, wherein the metal layer and the light absorption layer are spaced apart from each other in a height direction of the light absorption layer.

16. The display panel of claim 1, wherein a side surface of the light absorption layer is inclined.

17. An electronic devices, comprising:
a display module; and
a memory storing data for an operation of the display module,
wherein the display module comprises:
a substrate;
a display layer disposed on the substrate;
an encapsulation layer disposed on the display layer;
a metal layer disposed on the encapsulation layer and including a tip portion that protrudes in one direction; and
a light absorption layer disposed on the metal layer.

18. The electronic devices of claim 17, wherein the metal layer comprises:
a first metal layer disposed on the encapsulation layer; and
a second metal layer disposed on the first metal layer and including the tip portion that protrudes further than a side surface of the first metal layer in a direction away from the side surface of the first metal layer.

19. The electronic devices of claim 17, wherein the display module further comprises a light transmission layer surrounding the metal layer and the light absorption layer.

20. The electronic devices of claim 17, wherein the metal layer and the light absorption layer are respectively provided as a plurality of metal layers and a plurality of light absorption layers, and
wherein the plurality of metal layers and the plurality of light absorption layers are alternately stacked.
